(19) United States
(12) Patent Application Publication
(10) Pub. No.: US 2024/0276728 A1
(43) Pub. Date: Aug. 15, 2024

(54) SEMICONDUCTOR DEVICE

(71) Applicant: Kioxia Corporation, Tokyo (JP)

(72) Inventors: Takefumi YAMAGATA, Yokkaichi Mie (JP); Akira YOTSUMOTO, Yokkaichi Mie (JP); Yohei YAMAGUCHI, Yokkaichi Mie (JP)

(21) Appl. No.: 18/438,263

(22) Filed: Feb. 9, 2024

(30) Foreign Application Priority Data
Feb. 10, 2023 (JP) 2023-019481

(51) Int. Cl. H10B 43/40; H10B 43/27; H10B 43/35

(52) U.S. Cl. CPC H10B 43/40; H10B 43/27; H10B 43/35

(57) ABSTRACT

A semiconductor device includes a via contact electrode extending in a first direction, a wiring connected to the via contact electrode and extending in a second direction, and an insulating layer on a side of the wiring opposite to the via contact electrode. The wiring includes a first conductive member and a first barrier conductive film covering a surface of the first conductive member on a side of the insulating layer. The via contact electrode includes a first electrode region extending in the first direction, and a second electrode region on the side of the insulating layer with respect to the first electrode region that has a length in the second direction larger than that of the first electrode region. A surface of the second electrode region on the side of the insulating layer is in contact with the first barrier conductive film and is entirely covered therewith.

### CROSS-REFERENCE TO RELATED APPLICATION(S)

This application is based upon and claims the benefit of priority from Japanese Patent Application No. 2023-019481, filed Feb. 10, 2023, the entire contents of which are incorporated herein by reference.

### FIELD

Embodiments described herein relate generally to a semiconductor device.

### BACKGROUND

A semiconductor device including a substrate, a via contact electrode extending in a direction intersecting a surface of the substrate, and a wiring connected to the via contact electrode is known.

### DESCRIPTION OF THE DRAWINGS

FIG. 1 is a schematic exploded perspective view showing an example of a configuration of a semiconductor device according to a first embodiment.

FIG. 2 is a schematic bottom view showing a partial configuration of a memory die.

FIG. 3 is a schematic cross-sectional view showing a partial configuration of the memory die.

FIG. 4 is a schematic cross-sectional view showing an enlarged part of FIG. 3.

FIG. 5 is a schematic cross-sectional view showing an enlarged portion indicated by A in FIG. 4.

FIG. 6 is a schematic bottom view illustrating configurations of a bit line and a via contact electrode.

FIG. 7 is a schematic cross-sectional view illustrating configurations of a bit line and a via contact electrode.

FIG. 8 is a schematic cross-sectional view illustrating a configuration of a bit line.

FIG. 9 is a schematic cross-sectional view illustrating configurations of a bit line and a via contact electrode.

FIG. 10 is a schematic cross-sectional view illustrating configurations of a wiring and a via contact electrode.

FIG. 11 is a schematic cross-sectional view illustrating a configuration of a wiring.

FIG. 12 is a schematic cross-sectional view illustrating configurations of a wiring and a via contact electrode.

FIGS. 13-40 are schematic cross-sectional views illustrating a manufacturing method of the semiconductor device according to the first embodiment.

FIG. 41 is a schematic cross-sectional view showing a partial configuration of a semiconductor device according to a comparative example.

FIGS. 42-44 are schematic cross-sectional views showing a partial configuration of a semiconductor device according to a second embodiment.

FIGS. 45-46 are schematic cross-sectional views showing a partial configuration of a semiconductor device according to a third embodiment.

### DETAILED DESCRIPTION

In general, according to one embodiment, a semiconductor device includes a substrate, a via contact electrode that extends in a first direction intersecting a surface of the substrate, a first wiring that is connected to the via contact electrode and extends in a second direction intersecting the first direction, and an insulating layer that is provided on a side of the first wiring opposite to the via contact electrode in the first direction. The first wiring includes a first conductive member that extends in the second direction, and a first barrier conductive film that covers a surface of the first conductive member, that is on a side of the insulating layer in the first direction. The via contact electrode includes a first electrode region that extends in the first direction, and a second electrode region that is provided on the side of the insulating layer in the first direction with respect to the first electrode region and has a length in the second direction larger than a length of the first electrode region in the second direction. A surface of the second electrode region on the side of the insulating layer in the first direction is in contact with the first barrier conductive film and is entirely covered with the first barrier conductive film.

Next, the semiconductor device according to embodiments will be described in detail with reference to the drawings. The embodiments below are merely examples, and are not intended to limit the scope of the present disclosure. In addition, the drawings below are schematic, and for convenience of explanation, some configurations and the like may be omitted. Further, the same reference numerals may be given to parts common to the plurality of embodiments, and the description thereof may be omitted.

In the present specification, when the term “semiconductor device” is used, it may mean a die after dicing or may mean a wafer before dicing. The former case may mean a die after packaging or a die before packaging.

In the present specification, when a first configuration is “electrically connected” to a second configuration, the first configuration may be directly connected to the second configuration, or the first configuration may be connected to the second configuration via a wiring, a semiconductor member, a transistor, or the like. For example, when three transistors are connected in series, a first transistor is “electrically connected” to a third transistor even in a case where a second transistor is in an OFF state.

In the present specification, a case where the first configuration is “connected between” the second configuration and the third configuration may mean that the first configuration, the second configuration, and the third configuration are connected in series and the second configuration is connected to the third configuration via the first configuration.

In the present specification, a case where a circuit or the like causes two wirings and the like to be “electrically connected” may mean, for example, that the circuit or the like includes a transistor and the like, the transistor and the like are provided on a current path between the two wirings, and the transistor and the like are in an ON state.

In the present specification, a predetermined direction parallel to a surface of a substrate is referred to as an X direction, a direction which is parallel to the surface of the substrate and is perpendicular to the X direction is referred to as a Y direction, and a direction perpendicular to the surface of the substrate is referred to as a Z direction.

In the present specification, a direction along a predetermined surface may be referred to as a first direction, a direction intersecting the first direction along the predetermined surface may be referred to as a second direction, and a direction intersecting the predetermined surface may be referred to as a third direction. The first direction, the second direction, and the third direction may or may not correspond to any of the X direction, the Y direction, and the Z direction.

In the present specification, expressions such as “up” and “down” indicate directions relative to the substrate. For example, a direction away from the substrate along the Z direction is referred to as up, and a direction toward the substrate along the Z direction is referred to as down. When referring to a lower surface or a lower end of a certain configuration, it means a surface or an end portion on a side of the substrate of the configuration, and when referring to an upper surface or an upper end, it means a surface or an end portion on an opposite side of the substrate of the configuration. A surface intersecting the X direction or the Y direction is referred to as a side surface or the like.

Further, in the present specification, when referring to a “width”, a “length”, a “thickness”, or the like in a predetermined direction for a configuration, a member, and the like, it may mean the width, the length, the thickness, or the like in a cross section or the like observed by scanning electron microscopy (SEM), transmission electron microscopy (TEM), or the like.

### First Embodiment

### Structure of Memory Die MD

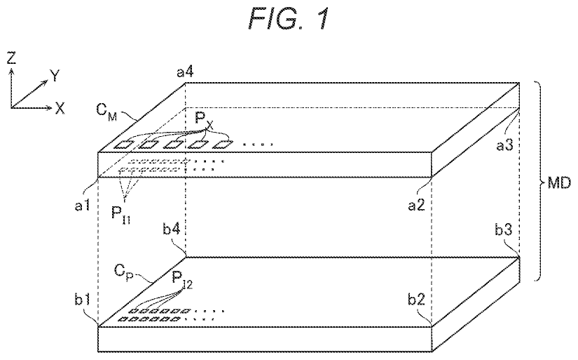

FIG. 1 is a schematic exploded perspective view showing an example of a configuration of a semiconductor device according to the present embodiment. The semiconductor device according to the first embodiment includes a memory die MD. As illustrated in FIG. 1, the memory die MD includes a chip C_{M} on a memory cell array side and a chip C_{P} on a peripheral circuit side.

A plurality of external pad electrodes P_{X} to which a bonding wire (not shown) can be connected are provided on an upper surface of the chip C_{M}. A plurality of bonding electrodes P_{I1}are provided on a lower surface of the chip C_{M}. A plurality of bonding electrodes P_{I2} are provided on an upper surface of the chip C_{P}. Regarding the chip C_{M}, a surface on which the plurality of bonding electrodes P_{I1} are provided is referred to as a front surface, and a surface on which the plurality of external pad electrodes P_{X} are provided is referred to as a back surface.

Regarding the chip C_{P}, a surface on which the plurality of bonding electrodes P_{I2} are provided is referred to as a front surface, and a surface on an opposite side of the front surface is referred to as a back surface. In the example illustrated in FIG. 1, the front surface of the chip C_{P} is provided above the back surface of the chip C_{P}, and the back surface of the chip C_{M} is the provided above the front surface of the chip C_{M}.

The chip C_{M} and the chip C_{P} are disposed such that the front surface of the chip C_{M} and the front surface of the chip C_{P} face each other. The plurality of bonding electrodes P_{I1} are provided respectively corresponding to the plurality of bonding electrodes P_{I2}, and are disposed at locations bondable to the plurality of bonding electrodes P_{I2}. The bonding electrode P_{I1} and the bonding electrode P_{I2} have a function of bonding the chip C_{M} and the chip C_{P} and electrically connecting the chip C_{M} and the chip C_{P}.

In the example of FIG. 1, corners a1, a2, a3, and a4 of the chip C_{M} correspond to corners b1, b2, b3, and b4 of the chip C_{P}, respectively.

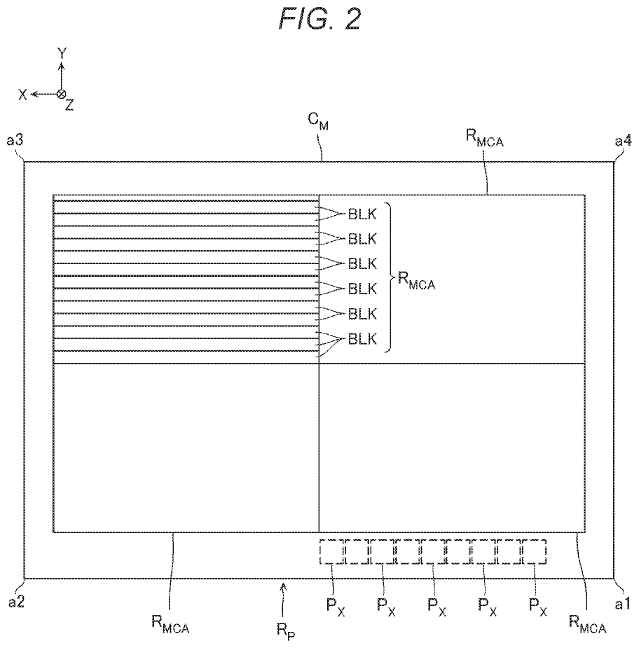

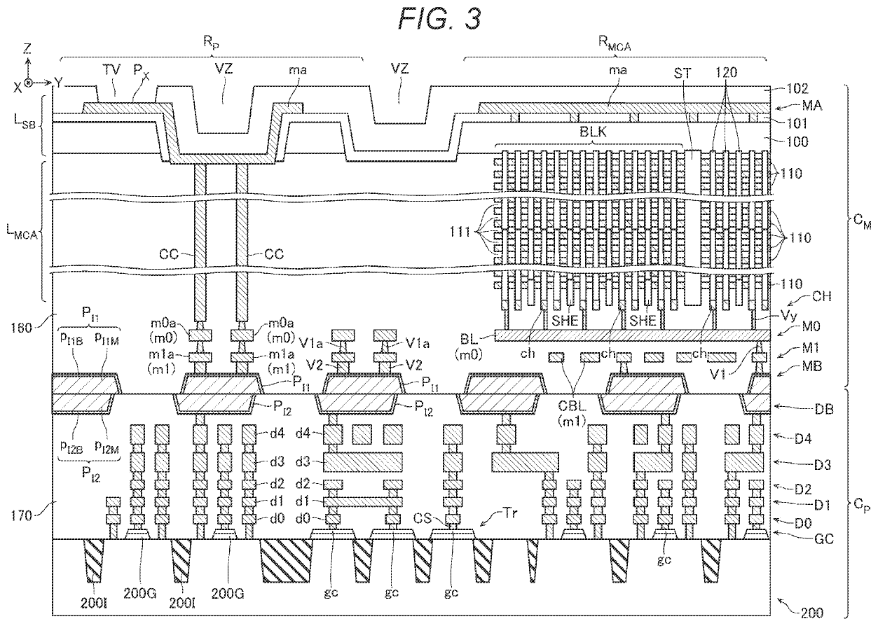

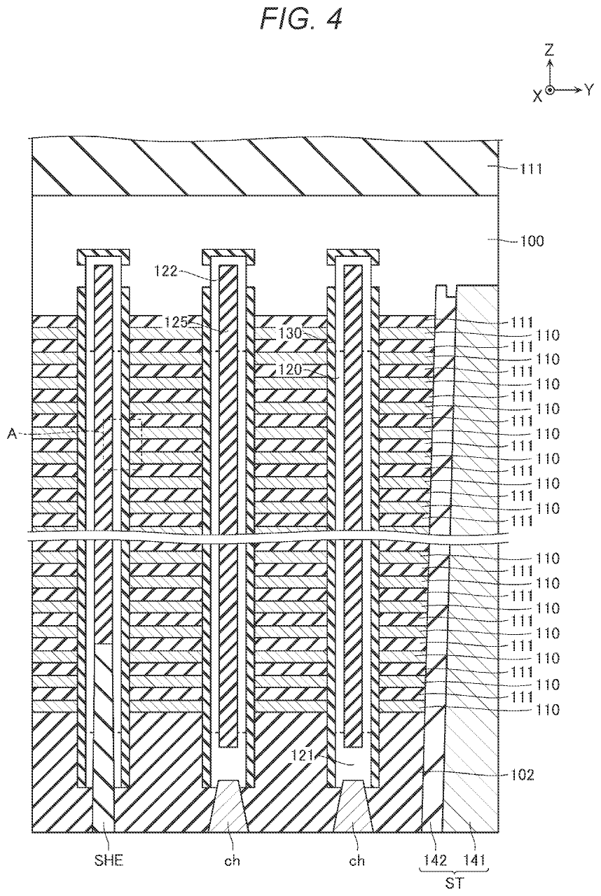

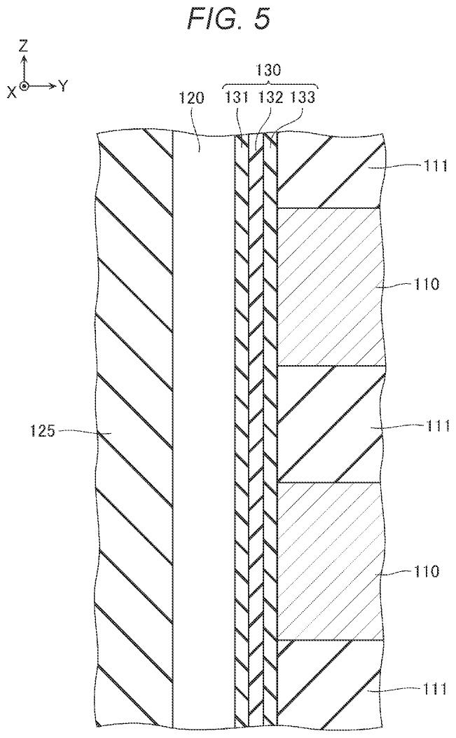

FIG. 2 is a schematic bottom view showing a partial configuration of the memory die MD. FIG. 3 is a schematic cross-sectional view showing a partial configuration of the memory die MD. FIG. 4 is a schematic cross-sectional view showing an enlarged part of FIG. 3. FIG. 5 is a schematic cross-sectional view showing an enlarged portion indicated by A in FIG. 4. FIG. 5 illustrates a YZ cross section, and a structure similar to that in FIG. 5 is observed even when a cross section other than the YZ cross section (for example, an XZ cross section) along the central axis of a semiconductor pillar 120 is observed.

### Structure of Chip C_{M}

For example, as shown in FIG. 2, the chip C_{M} includes four memory cell array regions R_{MCA} arranged in the X direction and the Y direction. In addition, the chip C_{M} includes a peripheral region R_{P} provided outside the four memory cell array regions R_{MCA}. A plurality of external pad electrodes P_{X} arranged in the X direction are provided in the peripheral region R_{P}.

As shown in FIG. 3, the chip C_{M} includes a base structure L_{SB}, a memory cell array layer L_{MCA} provided below the base structure L_{SB}, and a plurality of wiring layers CH, M0, M1, and MB provided below the memory cell array layer L_{MCA}.

Structure of Base Structure L_{SB} of Chip C_{M}

For example, as shown in FIG. 3, the base structure L_{SB} includes a conductive layer 100 provided on the upper surface of the memory cell array layer L_{MCA}, an insulating layer 101 provided on the upper surface of the conductive layer 100, a back surface wiring layer MA provided on the upper surface of the insulating layer 101, and an insulating layer 102 provided on the upper surface of the back surface wiring layer MA.

The conductive layer 100 may include, for example, a semiconductor layer such as silicon (Si) into which N-type impurities such as phosphorus (P) or P-type impurities such as boron (B) are implanted, may include a metal such as tungsten (W), or may include a silicide such as tungsten silicide (WSi).

The conductive layer 100 functions as a part of a source line of the NAND flash memory. A plurality of the conductive layers 100 are provided corresponding to a plurality of the memory cell arrays. A region VZ that does not include the conductive layer 100 is provided in a region corresponding to the end portion of the memory cell array.

The insulating layer 101 contains, for example, silicon oxide (SiO₂) and the like.

The back surface wiring layer MA includes a plurality of wirings ma. The plurality of wirings ma may include, for example, aluminum (Al).

Some of the plurality of wirings ma function as a part of the source line of the NAND flash memory. The wirings ma are provided in plural corresponding to the plurality of memory cell array regions R_{MCA}. The wirings ma are each electrically connected to the conductive layer 100.

Others of the plurality of wirings ma function as an external pad electrode P_{X}. The wirings ma are connected to the via contact electrode CC in the memory cell array layer L_{MCA} in the region VZ not including the conductive layer 100. In addition, some of the wirings ma are exposed to the outside of the memory die MD through an opening TV provided in the insulating layer 102 and are connected to a bonding wire (not shown).

The insulating layer 102 is, for example, a passivation layer including a resin material such as polyimide in the upper layer portion.

Structure in Memory Cell Array Region R_{MCA} of Memory Cell Array Layer L_{MCA} of Chip C_{M}

As shown in FIG. 2, a plurality of memory blocks BLK arranged in the Y direction are provided in the memory cell array layer L_{MCA}. As shown in FIG. 3, an inter-block structure ST is provided between two memory blocks BLK adjacent to each other in the Y direction.

For example, as illustrated in FIG. 4, the memory block BLK includes a plurality of conductive layers 110 arranged in the Z direction, a plurality of semiconductor pillars 120 extending in the Z direction, and a plurality of gate insulating films 130 respectively provided between the plurality of conductive layers 110 and the plurality of semiconductor pillars 120. An interlayer insulating layer 111 made of silicon oxide (SiO₂) or the like is provided between the plurality of conductive layers 110 arranged in the Z direction.

The conductive layer 110 has a substantially plate-like shape extending in the X direction. The conductive layer 110 may include a stacked film of a barrier conductive film made of titanium nitride (TiN) or the like and a conductive member made of tungsten (W) or the like. The conductive layer 110 may contain, for example, polycrystalline silicon containing impurities such as phosphorus (P) or boron (B).

In the present specification, when the term “barrier conductive film” is used, the barrier conductive film may contain titanium nitride (TiN) or may contain other materials such as tantalum nitride (TaN), tungsten nitride (WN), and titanium (Ti).

In addition, one or a plurality of conductive layers 110 located in the uppermost layer among the plurality of conductive layers 110 function as a select gate line of a NAND flash memory and a gate electrode of a plurality of select transistors connected to the select gate line. The one or the plurality of conductive layers 110 are electrically independent for each memory block BLK.

In addition, the plurality of conductive layers 110 located below the one or the plurality of conductive layers 110 function as a word line of the NAND flash memory and a gate electrode of the plurality of memory cells (memory transistors) connected to the word line. The plurality of conductive layers 110 are electrically independent for each memory block BLK.

In addition, one or a plurality of conductive layers 110 located below the plurality of conductive layers 110 function as a select gate line of the NAND flash memory and a gate electrode of the plurality of select transistors connected to the select gate line. The one or the plurality of conductive layers 110 are electrically independent from each other in units smaller than the memory block BLK. The one or the plurality of conductive layers 110 have a width in the Y direction smaller than the conductive layer 110 functioning as a word line or the like of the NAND flash memory. Some of the one or the plurality of conductive layers 110 is provided between the inter-block structure ST and the insulating layer SHE made of silicon oxide (SiO₂) or the like. Although not shown, others of the one or the plurality of conductive layers 110 is provided between the two insulating layers SHE adjacent to each other in the Y direction.

The semiconductor pillars 120 are arranged in a predetermined pattern in the X direction and the Y direction. The semiconductor pillar 120 functions as a channel region of a memory cell and a channel region of a select transistor of a NAND flash memory. The semiconductor pillar 120 contains, for example, polycrystalline silicon (Si). The semiconductor pillar 120 has a substantially cylindrical shape, and an insulating layer 125 made of silicon oxide or the like is provided at a central portion of the semiconductor pillar 120. An outer peripheral surface of the semiconductor pillar 120 is surrounded by the plurality of conductive layers 110, and faces the plurality of conductive layers 110.

An impurity region 121 is provided at a lower end of the semiconductor pillar 120. The impurity region 121 contains, for example, N-type impurities such as phosphorus (P). In the example of FIG. 4, a boundary line of the impurity region 121 is indicated by a broken line. The impurity region 121 is connected to a bit line BL via a via contact electrode ch and a via contact electrode Vy (FIG. 3).

An impurity region 122 is provided at an upper end of the semiconductor pillar 120. The impurity region 122 is connected to the conductive layer 100. In the example of FIG. 4, a boundary line of the impurity region 122 is indicated by a broken line. The impurity region 122 contains, for example, N-type impurities such as phosphorus (P) or P-type impurities such as boron (B).

The gate insulating film 130 has a substantially cylindrical shape that covers the outer peripheral surface of the semiconductor pillar 120. For example, as illustrated in FIG. 5, the gate insulating film 130 includes a tunnel insulating film 131, a charge storage film 132, and a block insulating film 133, which are stacked between the semiconductor pillar 120 and the conductive layer 110. The tunnel insulating film 131 and the block insulating film 133 contain, for example, silicon oxide (SiO₂). The charge storage film 132 includes, for example, a film that is made of silicon nitride (SiN) and is capable of storing charges. The tunnel insulating film 131, the charge storage film 132, and the block insulating film 133 have a substantially cylindrical shape, and extend in the Z direction along the outer peripheral surface of the semiconductor pillar 120 excluding a contact portion between the semiconductor pillar 120 and the conductive layer 100.

FIG. 5 illustrates an example in which the gate insulating film 130 includes the charge storage film 132 made of silicon nitride or the like. The gate insulating film 130 may include, for example, a floating gate made of polycrystalline silicon containing N-type or P-type impurities.

The inter-block structure ST includes, for example, a conductive layer 141 extending in the Z direction and the X direction and an insulating layer 142 provided on a side surface of the conductive layer 141, as shown in FIG. 4. The conductive layer 141 is connected to the conductive layer 100. For example, the conductive layer 141 may include a stacked film of a barrier conductive film made of titanium nitride (TiN) or the like and a conductive member made of tungsten (W) or the like. The conductive layer 141 functions as, for example, a part of a source line of a NAND flash memory. The insulating layer 142 contains, for example, silicon oxide (SiO₂).

Structure in Peripheral Region R_{P} of Memory Cell Array Layer L_{MCA} of Chip C_{M}

For example, as shown in FIG. 3, a plurality of the via contact electrodes CC are provided in the peripheral region R_{P}of the memory cell array layer L_{MCA}. The plurality of via contact electrodes CC are connected to the wiring ma at the upper ends thereof.

### Structure of Wiring Layer CH, M0, M1, and MB of Chip C_{M}

For example, as shown in FIG. 3, the plurality of wirings provided in the wiring layers CH, M0, M1, and MB are electrically connected to at least one of the configuration of the memory cell array layer L_{MCA} and the configuration in the chip C_{P}.

The wiring layer CH includes a plurality of via contact electrodes ch as a plurality of wirings. The plurality of via contact electrodes ch may include, for example, a stacked film of a barrier conductive film made of titanium nitride (TiN) or the like and a conductive member made of tungsten (W) or the like. The via contact electrode ch is provided to correspond to the plurality of semiconductor pillars 120 and is connected to lower ends of the plurality of semiconductor pillars 120.

The wiring layer M0 includes a plurality of wirings m0. The plurality of wirings m0 may include, for example, a stacked film of a barrier conductive film made of titanium nitride (TiN) or the like and a conductive member made of copper (Cu) or the like. Some of the plurality of wirings m0 are disposed in the memory cell array region R_{MCA} and function as a bit line BL. In addition, others of the plurality of wirings m0 (hereinafter, referred to as “wiring m0a”) are disposed in the peripheral region R_{P}.

A plurality of via contact electrodes V1 and V1a are provided between the wiring layer M0 and the wiring layer M1. The plurality of via contact electrodes V1 and V1a may include, for example, a stacked film of a barrier conductive film made of titanium nitride (TiN) or the like and a conductive member made of tungsten (W) or the like. The via contact electrodes V1 are disposed in the memory cell array region R_{MCA} and are connected to the lower surface of the bit line BL. The via contact electrodes V1a are disposed in the peripheral region R_{P} and are connected to the lower surface of the wiring m0a.

For example, as illustrated in FIG. 3, the wiring layer M1 includes a plurality of wirings m1. The plurality of wirings m1 may include, for example, a stacked film of a barrier conductive film made of titanium nitride (TiN) or the like and a conductive member made of tungsten (W) or the like. Some of the plurality of wirings m1 (hereinafter, referred to as “wiring CBL”) are disposed in the memory cell array region R_{MCA}, and connected to a lower end of the via contact electrode V1. In addition, others of the plurality of wirings m1 (hereinafter, referred to as “wiring m1a”) are disposed in the peripheral region R_{P} and connected to the lower end of the via contact electrode V1a.

A plurality of via contact electrodes V2 are provided between the wiring layer M1 and the wiring layer MB. The plurality of via contact electrodes V2 may include, for example, a stacked film of a barrier conductive film made of titanium nitride (TiN) or the like and a conductive member made of tungsten (W) or the like. The via contact electrodes V2 are connected to the lower surface of the wiring m1.

The wiring layer MB includes a plurality of bonding electrodes P_{I1}. The plurality of bonding electrodes P_{I1}may include, for example, a stacked film of a barrier conductive film p_{I1B} made of titanium nitride (TiN) or the like and a conductive member p_{I1M} made of copper (Cu) or the like. A part of the plurality of bonding electrodes P_{I1} are connected to a lower end of each of the via contact electrodes V2.

The wiring layers CH, M0, M1, and MB and the via contact electrodes Vy, V1, V1a, and V2 between the wiring layers CH, M0, M1, and MB are provided in the interlayer insulating layer 160 including, for example, a plurality of oxide layers and a plurality of nitride layers. In addition, the interlayer insulating layer 160 covers a periphery of a stacked body including a plurality of conductive layers 110 and a plurality of via contact electrodes CC, which are formed in the memory cell array region R_{MCA} and the peripheral region R_{P} in the memory cell array layer L_{MCA}.

### Structure of Chip C_{P}

The chip C_{P} includes, for example, a semiconductor substrate 200, an electrode layer GC provided above the semiconductor substrate 200, and wiring layers D0, D1, D2, D3, D4, and DB provided above the electrode layer GC, as shown in FIG. 3.

The semiconductor substrate 200 contains P-type silicon (Si) containing P-type impurities such as boron (B), for example. An N-type well region containing N-type impurities such as phosphorus (P), a P-type well region containing P-type impurities such as boron (B), a semiconductor substrate region in which the N-type well region and the P-type well region are not provided, and an insulating region 200I are provided on a surface of the semiconductor substrate 200. The N-type well region, the P-type well region, and the semiconductor substrate region each function as a part of the plurality of transistors Tr constituting the peripheral circuit and the plurality of capacitors or the like.

An electrode layer GC is provided on the upper surface of the semiconductor substrate 200 via an insulating layer 200G. The electrode layer GC includes a plurality of electrodes gc facing the surface of the semiconductor substrate 200 in the Z direction. Each of the regions of the semiconductor substrate 200 and the plurality of electrodes gc, which are provided in the electrode layer GC, is connected to a via contact electrode CS.

The N-type well region, the P-type well region, and the semiconductor substrate region of the semiconductor substrate 200 function as channel regions of a plurality of transistors Tr constituting a peripheral circuit, one electrode of a plurality of capacitors, and the like.

The plurality of electrodes gc, which are provided in the electrode layer GC, functions as gate electrodes of the plurality of transistors Tr constituting the peripheral circuit, the other electrodes of the plurality of capacitors, and the like.

The via contact electrode CS extends in the Z direction and is connected to the upper surface of the semiconductor substrate 200 or the upper surface of the electrode gc at the lower end of the via contact electrode CS. An impurity region containing N-type impurities or P-type impurities is provided at a portion at which the via contact electrode CS and the semiconductor substrate 200 are connected to each other. The via contact electrode CS may include, for example, a stacked film of a barrier conductive film made of titanium nitride (TiN) or the like and a conductive member made of tungsten (W) or the like.

The plurality of wirings provided in D0, D1, D2, D3, D4, and DB are electrically connected to at least one of the configuration of the memory cell array layer L_{MCA} and the configuration in the chip C_{P}, for example.

Each of the wiring layers D0, D1, and D2 includes a plurality of wirings d0, d1, and d2. The plurality of wirings d0, d1, and d2 may include, for example, a stacked film of a barrier conductive film made of titanium nitride (TiN) or the like and a conductive member made of tungsten (W) or the like.

Each of the wiring layers D3 and D4 includes a plurality of wirings d3 and d4. The plurality of wirings d3 and d4 may include, for example, a stacked film of a barrier conductive film made of titanium nitride (TiN) or the like and a conductive member made of copper (Cu) or the like.

The wiring layer DB includes a plurality of bonding electrodes P_{I2}. The plurality of bonding electrodes P_{I2} may include, for example, a stacked film of a barrier conductive film p_{I2B} made of titanium nitride (TiN) or the like and a conductive member p_{I2m} made of copper (Cu) or the like.

Here, when the conductive members p_{I1M} and p_{I2M} made of copper (Cu) or the like are used for the bonding electrode P_{I1} and the bonding electrode P_{I2}, the conductive member p_{I1M} and the conductive member p_{I2M} are integrated with each other, which makes it difficult to confirm the boundary between the conductive member p_{I1M}and the conductive member p_{I2M}. However, the bonded structure can be confirmed by distortion of bonded shape of the bonding electrode P_{I1} and the bonding electrode P_{I2} due to positional misalignment in bonding, and positional misalignment of the barrier conductive films p_{I1B} and p_{I2B} (generation of a discontinuous portion on the side surface). When the bonding electrode P_{I1} and the bonding electrode P_{I2} are formed by the damascene method, each of the side surfaces has a tapered shape. Therefore, in the shape of the cross section of the portion where the bonding electrode P_{I1} and the bonding electrode P_{I2} are bonded in the Z direction, the side wall does not have a linear shape, but has a non-rectangular shape. In addition, when the bonding electrode P_{I1} and the bonding electrode P_{I2} are bonded, the bottom surface, the side surface, and the upper surface of each Cu forming the bonding electrode P_{I1} and the bonding electrode P_{I2} are covered with the barrier metal. On the other hand, in a wiring layer using general Cu, an insulating layer (SiN, SiCN, or the like) having an oxidation preventing function of Cu is provided on the upper surface of Cu, and a barrier metal is not provided. Therefore, it is possible to distinguish the wiring layer from a general wiring layer even when there is no positional misalignment in bonding.

The electrode layer GC, the wiring layers D0, D1, D2, D3, D4, and DB, and the via structures for connecting the electrode layer GC and the wiring layers D0, D1, D2, D3, D4, and DB to each other are formed on the upper surface of the semiconductor substrate 200 and are provided in the interlayer insulating layer 170 including, for example, a plurality of oxide layers and a plurality of nitride layers. The interlayer insulating layers 160 and 170 are bonded on the surfaces where the interlayer insulating layers 160 and 170 are in contact with each other, and have a function of bonding the chip C_{M} and the chip C_{P} together with the bonding electrodes P_{I1} and P_{I2}.

### Structure of Bit Line BL and Via Contact Electrode V1

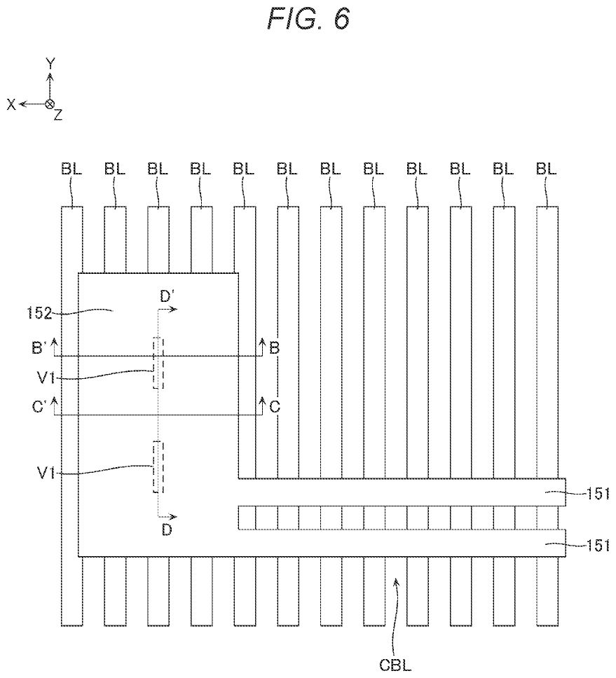

FIG. 6 is a schematic bottom view illustrating configurations of the bit line BL and the via contact electrode V1. As described with reference to FIG. 3, some of the plurality of wirings m0 function as a bit line BL. The bit lines BL are aligned in the X direction and extend in the Y direction. In addition, some of the plurality of wirings m1 function as a wiring CBL. The wiring CBL includes at least one portion 151 extending in the X direction, and a portion 152 connected to an end portion of the portion 151 in the X direction and electrically connected to the bit line BL via the via contact electrode V1.

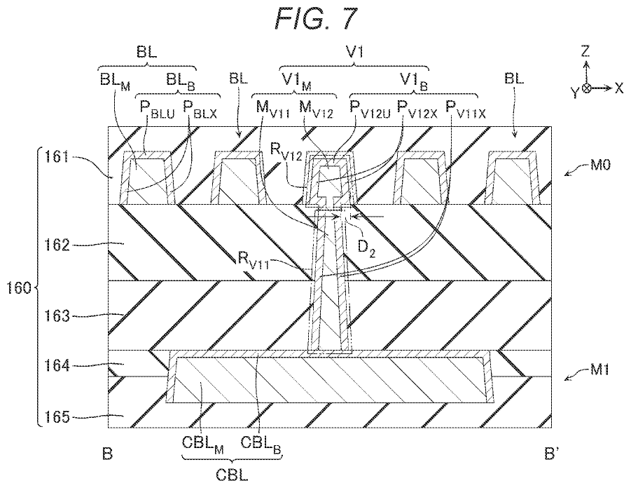

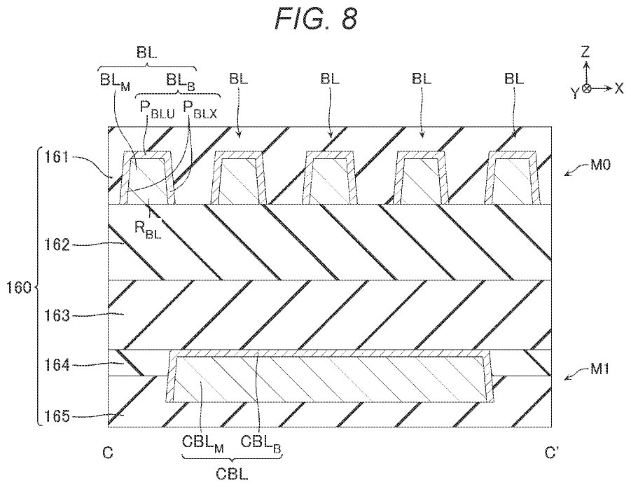

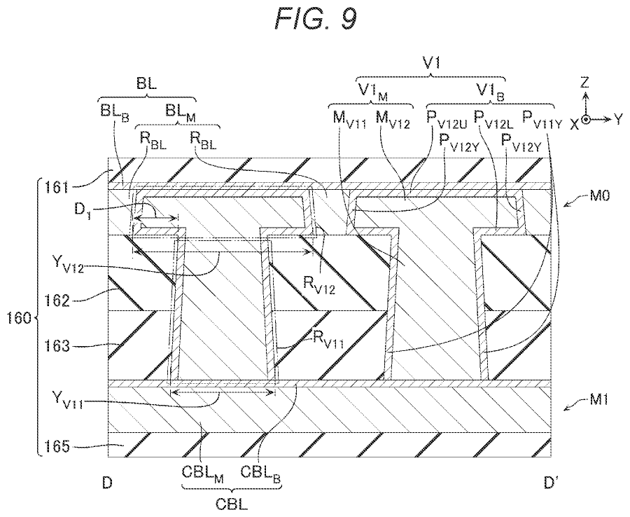

FIGS. 7 to 9 are schematic cross-sectional views for describing the configuration of the bit line BL and the via contact electrode V1. FIG. 7 shows a schematic cross section of the structure shown in FIG. 6 cut along the B-B′ line and viewed along the arrow. FIG. 8 shows a schematic cross section of the structure shown in FIG. 6 cut along the C-C′ line and viewed along the arrow. FIG. 9 shows a schematic cross section of the structure shown in FIG. 6 cut along the line D-D′ and viewed along the arrow.

As shown in FIG. 7, the interlayer insulating layer 160 includes an insulating layer 161 provided below the memory cell array layer L_{MCA} (FIG. 3), an insulating layer 162 provided below the insulating layer 161, an insulating layer 163 provided below the insulating layer 162, an insulating layer 164 provided below the insulating layer 163, and an insulating layer 165 provided below the insulating layer 164. The insulating layers 161, 163, and 165 contain, for example, silicon oxide (SiO₂). The insulating layers 162 and 164 contain, for example, silicon nitride (SiN).

In the shown example, the bit line BL is embedded in a groove provided on the lower surface of the insulating layer 161. The bit line BL includes a conductive member BL_{M} extending in the Y direction and a barrier conductive film BL_{B} covering the upper surface of the conductive member BL_{M} and both side surfaces of the conductive member BL_{M} in the X direction. In the shown example, the lower surface of the conductive member BL_{M} and the lower end of the barrier conductive film BL_{B} are in contact with the upper surface of the insulating layer 162. The barrier conductive film BL_{B} does not cover the lower surface of the conductive member BL_{M}.

As shown in FIG. 9, the conductive member BL_{M} includes a plurality of wiring regions R_{BL} arranged in the Y direction via the via contact electrode V1. The plurality of wiring regions R_{BL} are separated from each other in the Y direction.

As shown in FIG. 8, the barrier conductive film BL_{B} includes a portion P_{BLU} that covers the upper surface of the conductive member BL_{M} and a pair of portions P_{BLX} that cover both side surfaces of the conductive member BL_{M} in the X direction. The portions P_{BLU} and P_{BLX} each extend in the Y direction and are connected to the plurality of wiring regions R_{BL} arranged in the Y direction.

As shown in FIG. 9, the via contact electrode V1 includes an electrode region R_{V11} that extends in the Z direction through the insulating layers 163 and 162, and an electrode region R_{V12} that is provided above the electrode region R_{V11} and extends in the Y direction at a height position corresponding to the conductive member BL_{M}. A length Y_{V12} of the electrode region R_{V12} in the Y direction is larger than a length Y_{V11} of the electrode region R_{V11} in the Y direction (for example, a length Y_{V11} of the lower end of the electrode region R_{V11} in the Y direction).

The wiring region R_{BL} and the electrode region R_{V11} are provided at positions that do not overlap each other when viewed in the Z direction. The wiring region R_{BL} and the electrode region R_{V12} are provided at positions that overlap each other when viewed in the Y direction.

The upper surface of the electrode region R_{V12} is in contact with the lower surface of the portion P_{BLU} and is entirely covered with the portion P_{BLU}. In addition, as shown in FIG. 7, both side surfaces of the electrode region R_{V12} in the X direction are in contact with the portion P_{BLX} and are entirely covered with the portion P_{BLX}. In addition, as shown in FIG. 9, the electrode region R_{V12} is in contact with the side surface of the wiring region R_{BL} in the Y direction. In the shown example, the lower surface of a part of the electrode region R_{V12} (part provided at a position that does not overlap the electrode region R_{V11} when viewed in the Z direction) is in contact with the upper surface of the insulating layer 162.

FIG. 9 shows a distance D₁ in the Y direction from one end portion of the electrode region R_{V12} in the Y direction to the upper end of the electrode region R_{V11}. FIG. 7 shows a distance D₂ in the X direction from one end portion of the electrode region R_{V12} in the X direction to the upper end of the electrode region R_{V11}. The distance D₁ is larger than the distance D₂.

The via contact electrode V1 includes a conductive member V1_{M} and a barrier conductive film V1_{B} that covers the upper surface of the conductive member V1_{M}, both side surfaces of the conductive member V1_{M} in the X direction, and both side surfaces of the conductive member V1_{M} in the Y direction. In the shown example, the lower surface of the conductive member V1_{M} and the lower end of the barrier conductive film V1_{B} are in contact with the upper surface of the wiring CBL. The barrier conductive film V1_{B} does not cover the lower surface of the conductive member V1_{M}.

The conductive member V1_{M} includes a conductive region M_{V11} that extends in the

Z direction in the electrode region R_{V11} and a conductive region M_{V12} that extends in the Y direction in the electrode region R_{V12}.

The barrier conductive film V1_{B} includes a pair of portions P_{V11X} (FIG. 7) that cover both side surfaces of the conductive region M_{V11} in the X direction and a pair of portions P_{V11Y} (FIG. 9) that cover both side surfaces of the conductive region M_{V11} in the Y direction. Each of the portions P_{V11X} and P_{V11Y} extends in the Z direction along the conductive region M_{V11}.

In addition, the barrier conductive film V1_{B} includes a portion P_{V12U} that covers the upper surface of the conductive region M_{V12}, a pair of portions P_{V12X} (FIG. 7) that cover both side surfaces of the conductive region M_{V12} in the X direction, a pair of portions P_{V12Y} (FIG. 9) that cover both side surfaces of the conductive region M_{V12} in the Y direction, and a portion P_{V12L} (FIG. 9) that covers the lower surface of a part (part provided at a position that does not overlap the conductive region M_{V11} when viewed in the Z direction) of the conductive region M_{V12}.

As shown in FIG. 7, the wiring CBL is provided at a height position corresponding to the insulating layer 164 and a part of the insulating layer 165. The wiring CBL includes a conductive member CBL_{M} and a barrier conductive film CBL_{B} that covers the upper surface of the conductive member CBL_{M}, both side surfaces of the conductive member CBL_{M} in the X direction, and both side surfaces of the conductive member CBL_{M} in the Y direction. In the shown example, the lower surface of the conductive member CBL_{M} and the lower end of the barrier conductive film CBL_{B} are in contact with the insulating layer 165. The barrier conductive film CBL_{B} does not cover the lower surface of the conductive member CBL_{M}.

### Structure of Wiring m0a and Via Contact Electrode V1a

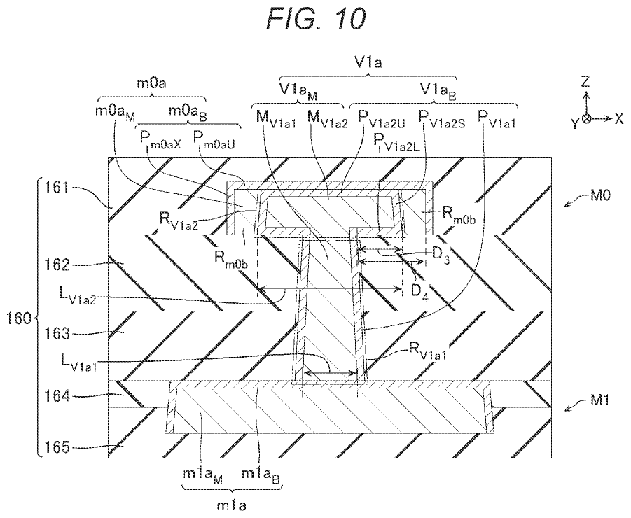

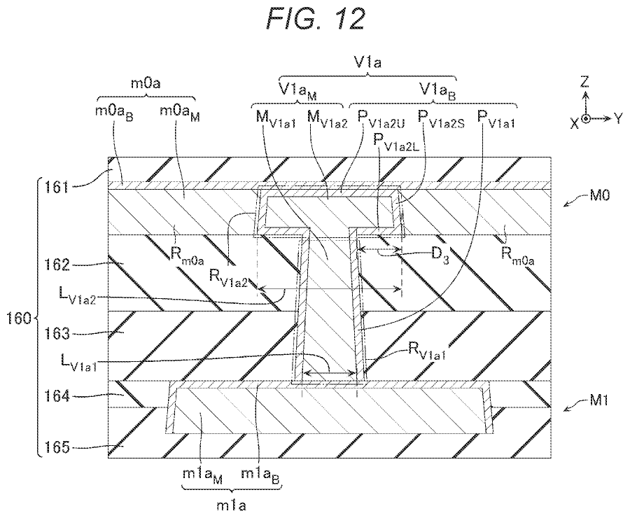

FIGS. 10 to 12 are schematic cross-sectional views for describing the configuration of the wiring m0a and the via contact electrode V1a. FIGS. 10 to 12 also show the insulating layers 161, 162, 163, 164, and 165 described with reference to FIGS. 7, 8 and 9. FIGS. 10 and 12 illustrate a wiring m0a, a via contact electrode V1a, and a wiring m1a.

In the shown example, the wiring m0a is embedded in a groove provided on the lower surface of the insulating layer 161. The wiring m0a includes a conductive member m0a_{M} that extends in the Y direction and a barrier conductive film m0a_{B} that covers the upper surface of the conductive member m0a_{M} and both side surfaces of the conductive member m0a_{M} in the X direction. In the example of FIG. 10, the lower surface of the conductive member m0a_{M} and the lower end of the barrier conductive film m0a_{B} are in contact with the upper surface of the insulating layer 162. The barrier conductive film m0a_{B} does not cover the lower surface of the conductive member m0a_{M}.

The conductive member m0a_{M} includes a plurality of wiring regions Rₘ₀ₐ (FIG. 12) arranged in the Y direction via the via contact electrode V1a and a pair of wiring regions R_{m0b} (FIG. 10) arranged in the X direction via the via contact electrode V1a. The plurality of wiring regions Rₘ₀ₐ are connected to each other via the wiring region R_{m0b}, and thus the conductive member m0a_{M} is continuous in the Y direction.

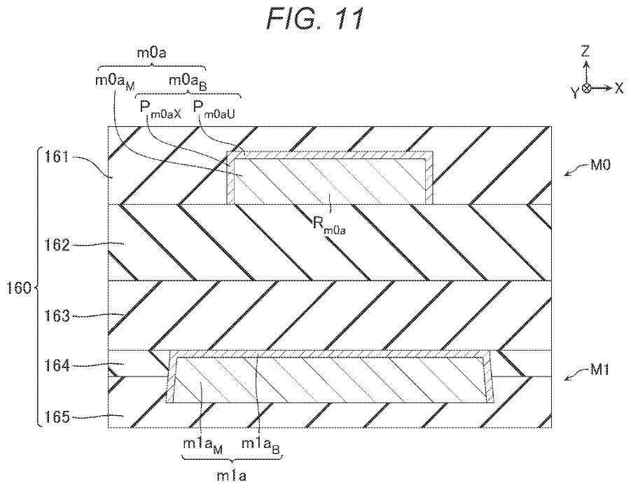

As shown in FIG. 11, the barrier conductive film m0a_{B} includes a portion P_{m0aU} that covers the upper surface of the conductive member m0a_{M} and a pair of portions P_{m0aX} that cover both side surfaces of the conductive member m0a_{M} in the X direction. The portions P_{m0aU} and P_{m0aX} are each connected to the plurality of wiring regions Rₘ₀ₐ, R_{m0b} arranged in the Y direction and extending in the Y direction.

The via contact electrode V1a includes a substantially columnar electrode region R_{V1a1} extending in the Z direction through the insulating layers 163 and 162, and a substantially disk-shaped electrode region R_{V1a2} provided above the electrode region R_{V1a1} and extending in the X direction and the Y direction at a height position corresponding to the conductive member m0a_{M}.

The length L_{V1a2} of the electrode region R_{V1a2} in the X direction and the Y direction is larger than the length L_{V1a1} of the electrode region R_{V1a1} in the X direction and the Y direction (for example, the length L_{V1a1} of the electrode region R_{V1a1} in the X direction and the Y direction at the lower end).

The wiring regions Rₘ₀ₐ and R_{m0b} and the electrode region R_{V1a1} are provided at positions that do not overlap each other when viewed in the Z direction. The wiring region Rₘ₀ₐ and the electrode region R_{V1a2} are provided at positions that overlap each other when viewed in the Y direction. The wiring region R_{m0b}and the electrode region R_{V1a2} are provided at positions that overlap each other when viewed in the X direction.

The upper surface of the electrode region R_{V1a2} is in contact with the lower surface of the portion P_{m0aU} and is entirely covered with the portion P_{m0aU}. In addition, the outer peripheral surface of the electrode region R_{V1a2} is in contact with the conductive member m0a_{M} over the entire circumference. In the shown example, the lower surface of a part of the electrode region R_{V1a2} (part provided at a position that does not overlap the electrode region R_{V1a1} when viewed in the Z direction) is in contact with the upper surface of the insulating layer 162.

FIGS. 10 and 12 show a distance D₃ in the X direction or the Y direction, from one end portion of the electrode region R_{V1a2} in the X direction or the Y direction to the upper end of the electrode region R_{V1a1}. In addition, FIG. 10 shows a distance D₄ in the X direction, from one end portion of the wiring region R_{m0b} in the X direction to the upper end of the electrode region R_{V1a1}. The distance D₃is smaller than the distance D₄. The distance D₃ may be equal to the distance D₁ in FIG. 9.

The via contact electrode V1a includes a conductive member V1a_{M} and a barrier conductive film V1a_{B} that covers the upper surface and the outer peripheral surface of the conductive member V1a_{M}. In the shown example, the lower surface of the conductive member V1a_{M}and the lower end of the barrier conductive film V1a_{B} are in contact with the upper surface of the wiring m1a. The barrier conductive film V1a_{B} does not cover the lower surface of the conductive member V1a_{M}.

The conductive member V1a_{M} includes a substantially columnar conductive region M_{V1a1} extending in the Z direction in the electrode region R_{V1a1} and a substantially disk-shaped conductive region M_{V1a2} extending in the X direction and the Y direction in the electrode region R_{V1a2}.

The barrier conductive film V1a_{B} includes a portion P_{V1a1} that covers the outer peripheral surface of the conductive region M_{V1a1}. The portion P_{V1a1} extends in the Z direction along the conductive region M_{V1a1}.

In addition, the barrier conductive film V1a_{B}includes a portion P_{V1a2U} that covers the upper surface of the conductive region M_{V1a2}, a portion P_{V1a2S} that covers the outer peripheral surface of the conductive region M_{V1a2}, and a portion P_{V1a2L} that covers the lower surface of a part (part provided at a position that does not overlap the conductive region M_{V1a1} when viewed in the Z direction) of the conductive region M_{V1a2}.

The wiring m1a is provided at a height position corresponding to the insulating layer 164 and a part of the insulating layer 165. The wiring m1a includes a conductive member m1a_{M}and a barrier conductive film m1a_{B} that covers the upper surface of the conductive member m1a_{M}, both side surfaces of the conductive member m1a_{M} in the X direction, and both side surfaces of the conductive member m1a_{M} in the Y direction. In the shown example, the lower surface of the conductive member m1a_{M}and the lower end of the barrier conductive film m1a_{B} are in contact with the insulating layer 165. The barrier conductive film m1a_{B} does not cover the lower surface of the conductive member m1a_{M}.

### Manufacturing Method

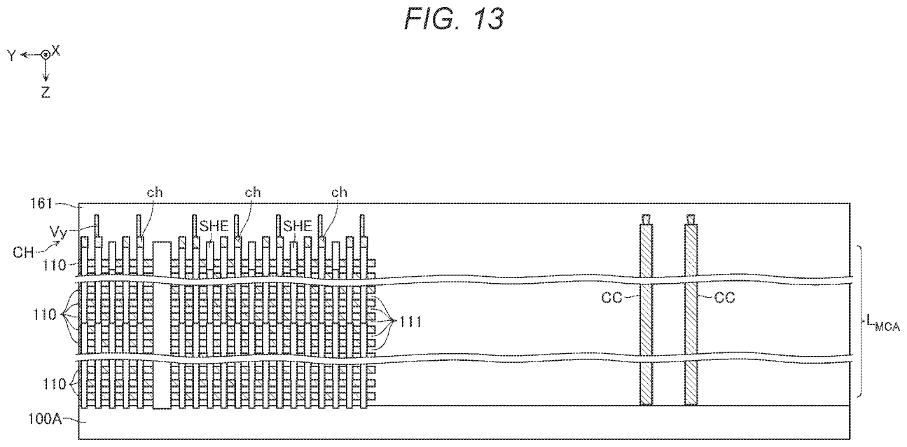

Next, a method of manufacturing the memory die MD will be described with reference to FIGS. 13 to 40. FIGS. 13 to 40 are schematic cross-sectional views for describing the manufacturing method. FIGS. 13, 39, and 40 show cross sections corresponding to FIG. 3. FIGS.

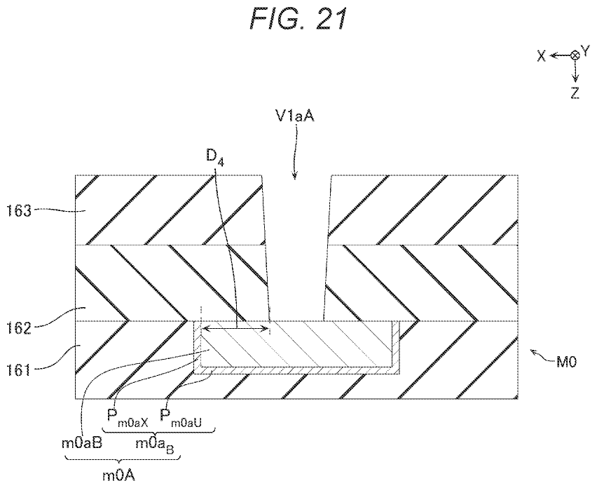

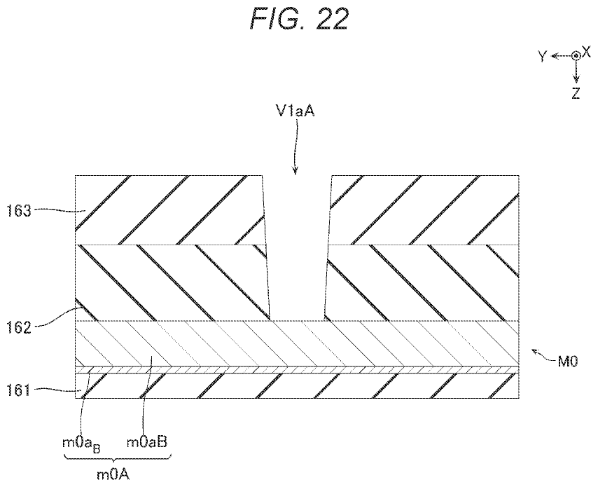

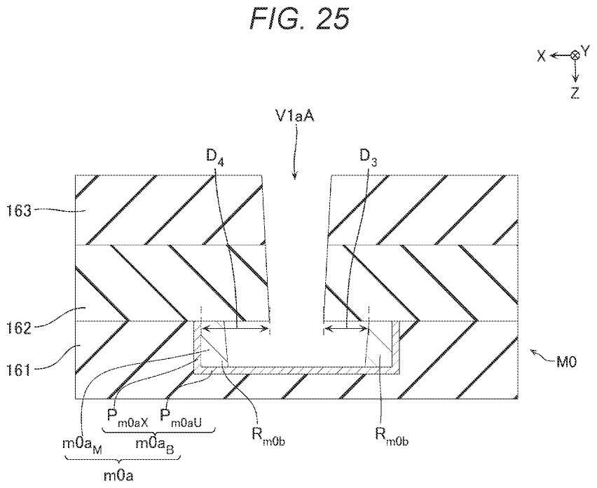

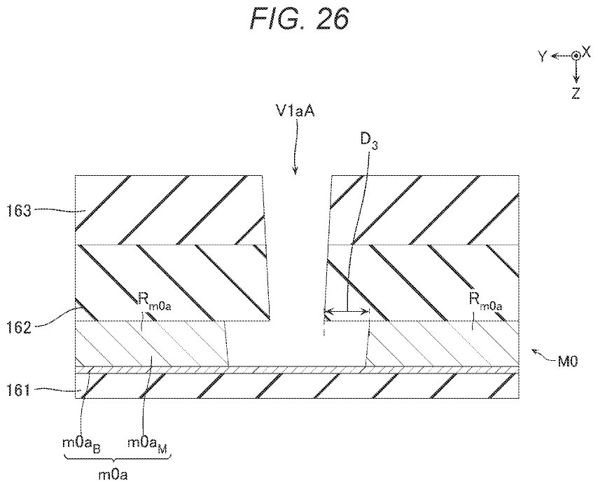

14 to 17, 19, 23, 27, 29, 31, 33, 35, and 37 show cross sections corresponding to FIG. 7. FIGS. 18, 20, 24, 28, 30, 32, 34, 36, and 38 show cross sections corresponding to FIG. 9. FIGS. 21 and 25 show cross sections corresponding to FIG. 10. FIGS. 22 and 26 show cross sections corresponding to FIG. 12.

In the manufacturing of the memory die MD according to the present embodiment, a structure as shown in FIG. 13 is created, for example. The illustrated structure includes a semiconductor layer 100A, a memory cell array layer L_{MCA} provided above the semiconductor layer 100A, a wiring layer CH provided above the memory cell array layer L_{MCA}, and a plurality of via contact electrodes Vy. The insulating layer 161 is formed above the memory cell array layer L_{MCA}.

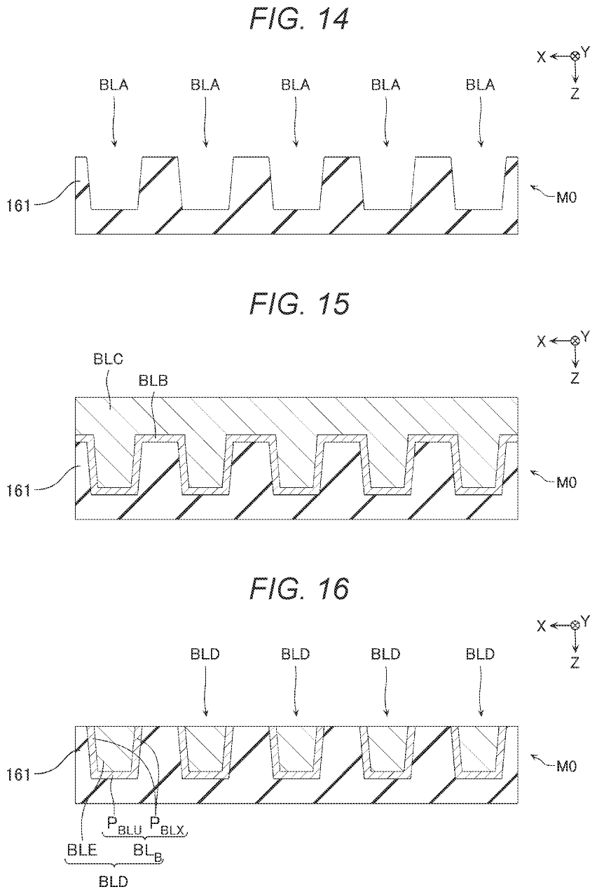

Next, for example, as shown in FIGS. 14 to 16, a plurality of the conductive layers BLD are formed in the wiring layer M0 by a damascene process.

For example, as shown in FIG. 14, a plurality of grooves BLA are formed in the insulating layer 161 at positions corresponding to the bit line BL. Although not shown, a groove is formed at a position corresponding to the wiring m0a (FIGS. 10 to 12). This step is performed by, for example, a method such as reactive ion etching (RIE).

Next, for example, as shown in FIG. 15, the barrier conductive film BLB and the conductive member BLC are formed. The barrier conductive film BLB is formed on the upper surface of the insulating layer 161, the bottom surface and the side surface of the groove BLA, and the bottom surface and the side surface of the groove corresponding to the wiring m0a. The grooves BLA and the grooves corresponding to the wiring m0a are embedded by the conductive member BLC. This step is performed by, for example, a method such as sputtering or plating.

Next, for example, as shown in FIG. 16, a flattening treatment is performed to remove parts of the barrier conductive film BLB and the conductive member BLC. This step is performed by, for example, a method such as chemical mechanical polishing (CMP).

In this step, other parts of the barrier conductive film BLB and the conductive member BLC remain in the groove BLA, and the barrier conductive film BL_{B} and the conductive member BLE are formed. In the shown example, a configuration including the barrier conductive film BL_{B} and the conductive member BLE is shown as the conductive layer BLD.

In addition, in this step, the other parts of the barrier conductive film BLB and the conductive member BLC remain inside the groove corresponding to the wiring m0a, and the barrier conductive film m0a_{B} and the conductive member m0aB (FIGS. 21 and 22) are formed. In the examples of FIGS. 21 and 22, the configuration including the barrier conductive film m0a_{B} and the conductive member m0aB is shown as the conductive layer m0A.

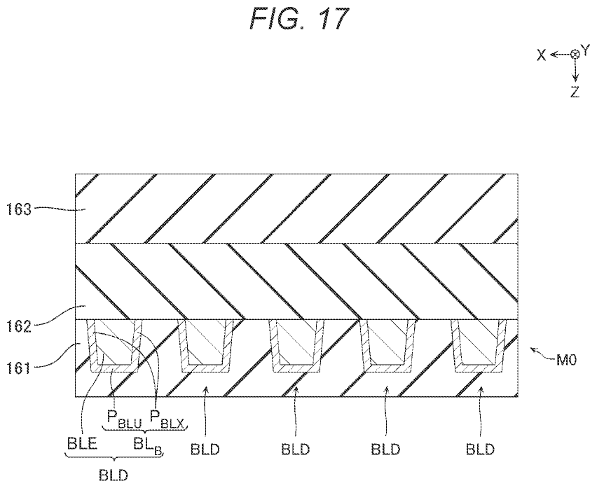

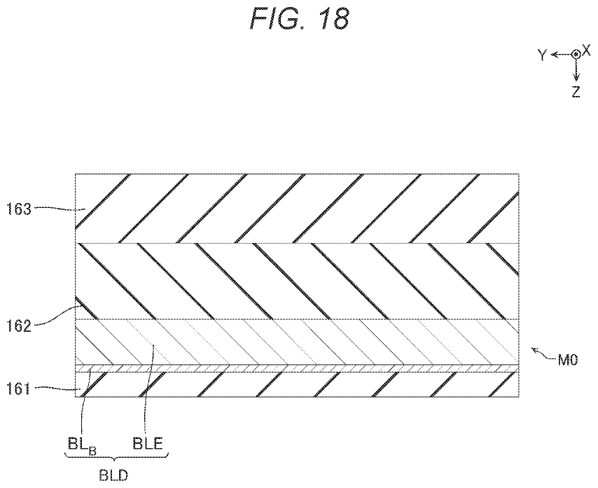

Next, for example, as shown in FIGS. 17 and 18, the insulating layers 162 and 163 are formed. This step is performed by, for example, a method such as chemical vapor deposition (CVD).

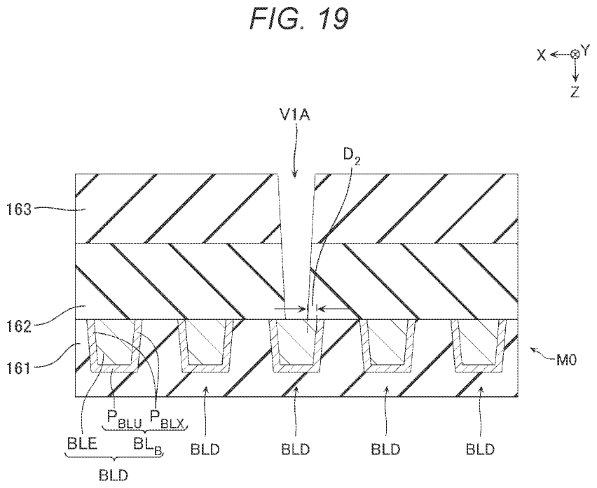

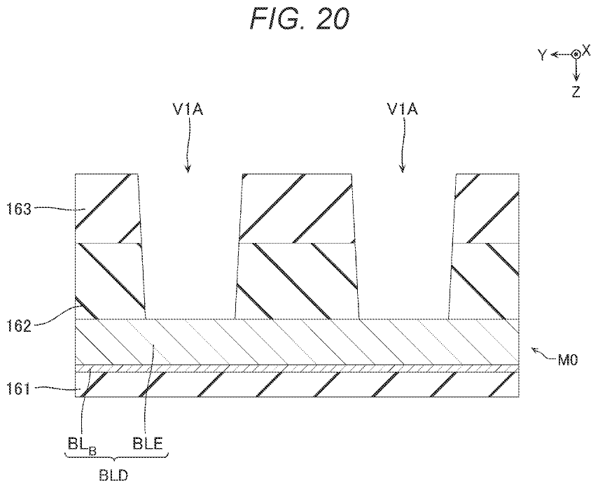

Next, for example, as shown in FIGS. 19 and 20, a contact hole V1A is formed at a position corresponding to the via contact electrode V1. The contact hole V1A penetrates the insulating layers 162 and 163 and extends in the Z direction to expose a part of the conductive layer BLD. In addition, for example, as shown in FIGS. 21 and 22, a contact hole V1aA is formed at a position corresponding to the via contact electrode V1a. The contact hole V1aA penetrates the insulating layers 162 and 163 and extends in the Z direction to expose a part of the conductive layer m0A. This step is performed by, for example, a method such as RIE.

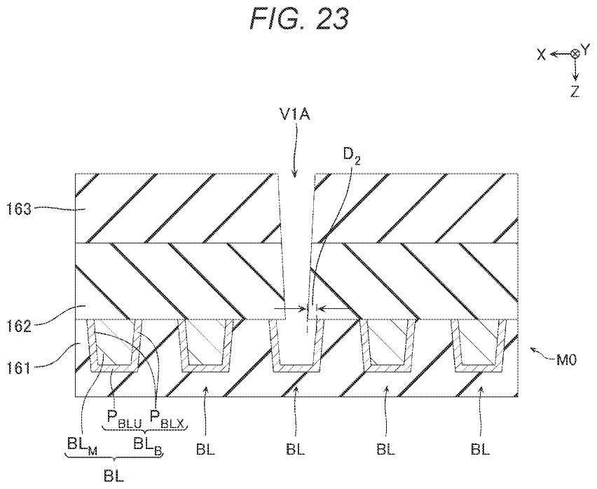

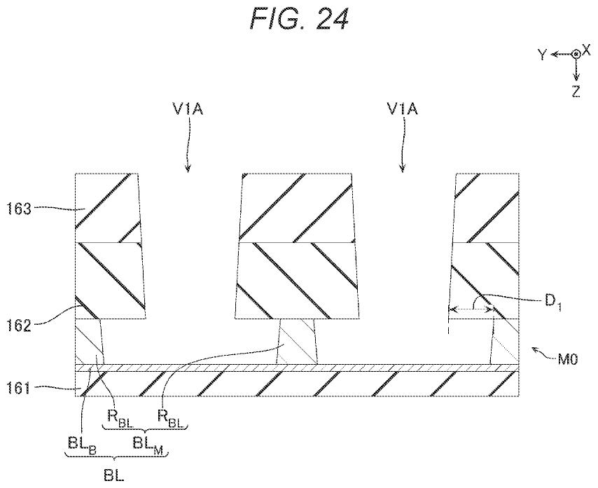

Next, for example, as shown in FIGS. 23 and 24, a part of the conductive member BLE is removed. In addition, in this step, for example, as shown in FIGS. 25 and 26, a part of the conductive member m0aB is removed. This step is performed by, for example, a method such as wet etching. This step is performed under the condition that the etching rate of the material forming the conductive members BLE and m0aB is sufficiently larger than the etching rate of the material forming the barrier conductive films BL_{B} and m0a_{B}.

In this step, as shown in FIGS. 23 and 24, a part of the conductive member BLE is removed in a certain range, so that parts of portions P_{BLU} and P_{BLX} of the barrier conductive film BL_{B} are exposed. Therefore, the distance D₁ (FIG. 24) at which the conductive member BLE is removed is larger than the distance D₂ (FIG. 19 and FIG. 23) in the X direction from the end portion in the X direction of the surface on the negative side in the Z direction of the conductive member BLE to the contact hole V1A.

In this step, as shown in FIGS. 25 and 26, a part of the portion P_{m0aU} of the barrier conductive film m0a_{B}is exposed. The portion P_{m0aX}of the barrier conductive film m0a_{B} is not exposed. Therefore, the distance D₃ (FIGS. 25 and 26) at which the conductive member m0aB is removed is smaller than the distance D₄ (FIGS. 21 and 25) in the X direction from the end portion in the X direction of the surface on the negative side in the Z direction of the conductive member m0aB to the contact hole V1aA. The distance D₃ may be equal to the distance D₁ in FIG. 24.

In this step, as shown in FIGS. 23 and 24, the conductive member BLE is divided into a plurality of wiring regions R_{BL} in the Y direction, and the conductive member BL_{M} of the bit line BL is formed. In addition, as shown in FIGS. 25 and 26, the conductive member m0a_{M} of the wiring m0a is formed.

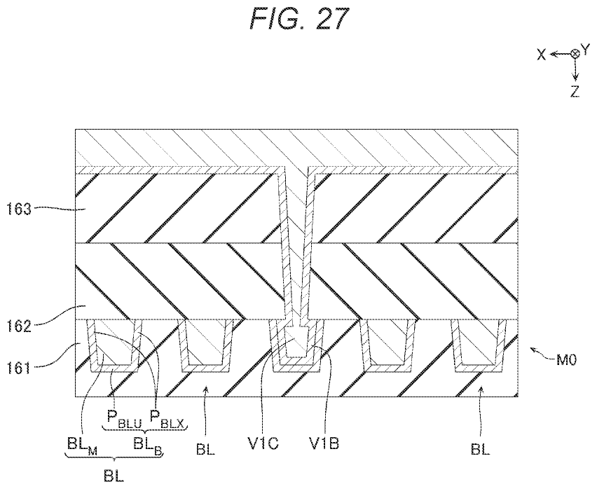

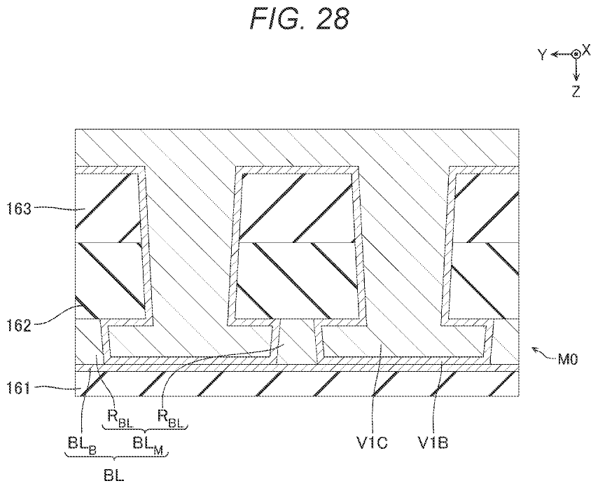

Next, for example, as shown in FIGS. 27 and 28, the barrier conductive film V1B and the conductive member V1C are formed. The barrier conductive film V1B is formed on the upper surface of the insulating layer 163, the bottom surface and the inner peripheral surface of the contact hole V1A, and the bottom surface and the inner peripheral surface of the contact hole V1aA. The contact holes V1A and V1aA are embedded by the conductive member V1C. This step is performed by, for example, a method such as CVD.

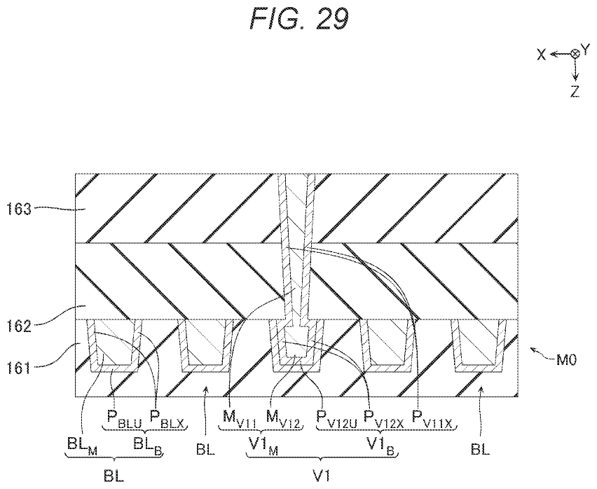

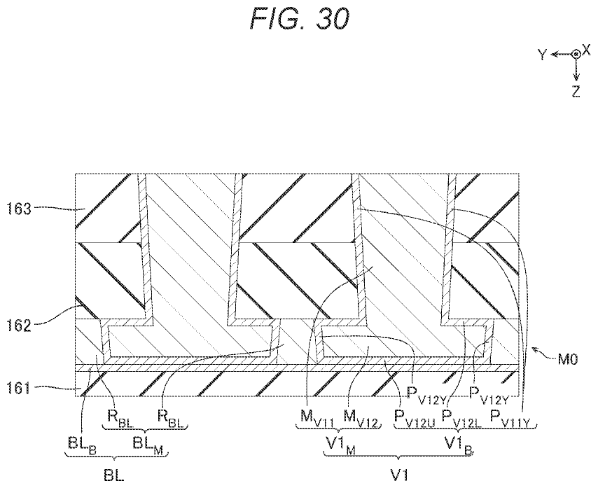

Next, for example, as shown in FIGS. 29 and 30, a flattening treatment is performed to remove parts of the barrier conductive film V1B and the conductive member V1C. This step is performed by, for example, a method such as CMP.

In this step, other parts of the barrier conductive film V1B and the conductive member V1C remain inside the contact hole V1A, and the barrier conductive film V1_{B} and the conductive member V1_{M} are formed.

Although not shown, in this step, the other parts of the barrier conductive film V1B and the conductive member V1C remain inside the contact hole V1aA, and the barrier conductive film V1a_{B} and the conductive member V1a_{M} (FIGS. 10 and 12) are formed.

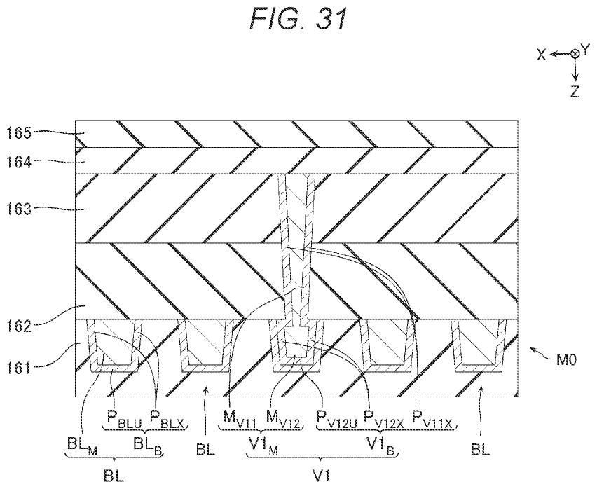

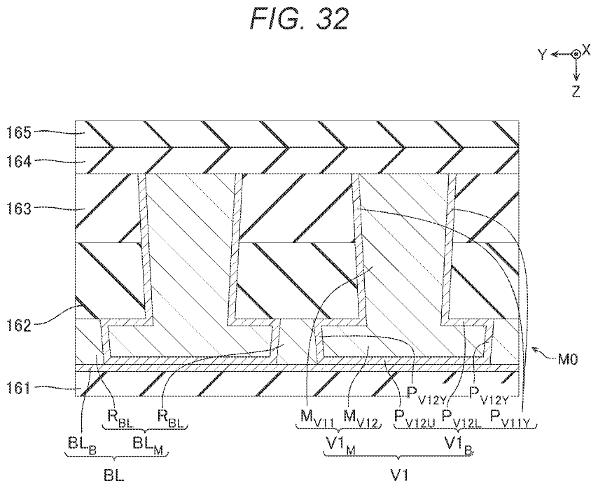

Next, for example, as shown in FIGS. 31 and 32, the insulating layer 164 and a part of the insulating layer 165 are formed. This step is performed by, for example, a method such as CVD.

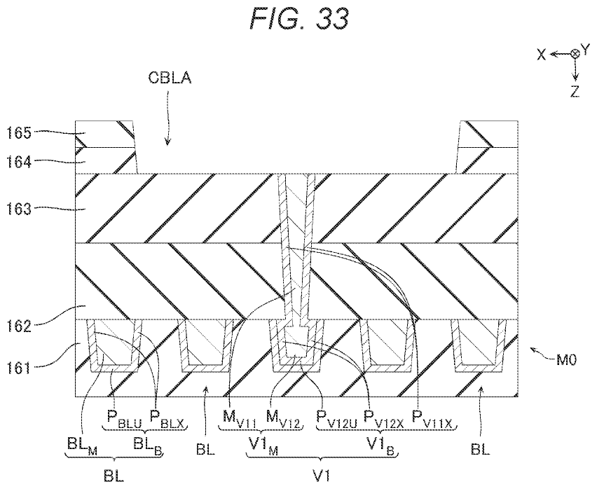

Next, for example, as shown in FIGS. 33 to 38, the wiring m1 such as the wiring CBL is formed in the wiring layer M1 by a damascene process.

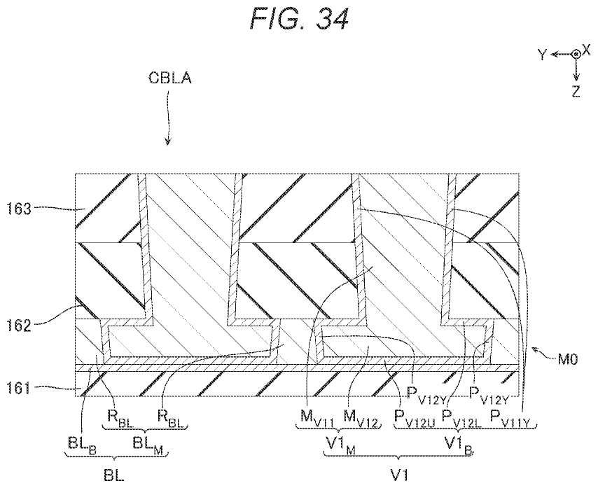

For example, as shown in FIGS. 33 and 34, a plurality of grooves CBLA are formed at positions corresponding to the wiring CBL in the insulating layer 164 and a part of the insulating layer 165. Although not shown, a groove is formed at a position corresponding to the wiring m1a (FIGS. 10 and 12). This step is performed by, for example, a method such as RIE.

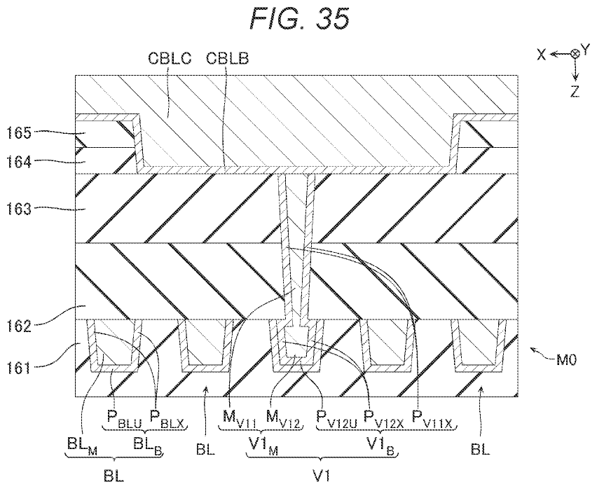

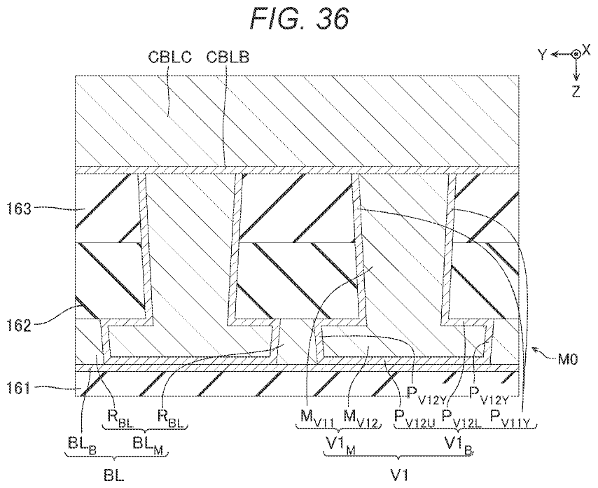

Next, for example, as shown in FIGS. 35 and 36, the barrier conductive film CBLB and the conductive member CBLC are formed. The barrier conductive film CBLB is formed on the upper surface of a part of the insulating layer 165, the bottom surface and the side surface of the groove CBLA, and the bottom surface and the side surface of the groove corresponding to the wiring m1a. The groove CBLA and the groove corresponding to the wiring m1a are embedded by the conductive member CBLC. This step is performed by, for example, a method such as CVD.

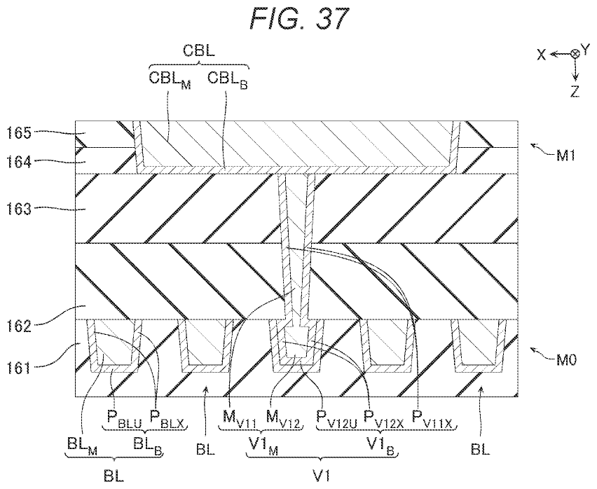

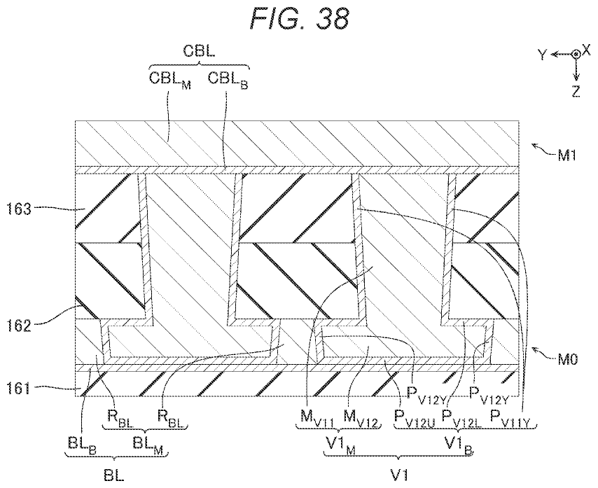

Next, for example, as shown in FIGS. 37 and 38, a flattening treatment is performed to remove parts of the barrier conductive film CBLB and the conductive member CBLC. This step is performed by, for example, a method such as CMP.

In this step, other parts of the barrier conductive film CBLB and the conductive member CBLC remain inside the groove CBLA, and the barrier conductive film CBL_{B} and the conductive member CBL_{M} are formed.

In this step, the other parts of the barrier conductive film CBLB and the conductive member CBLC remain inside the groove corresponding to the wiring m1a, and the barrier conductive film m1a_{B} and the conductive member m1a_{M} (FIG. 10 and FIG. 12) are formed.

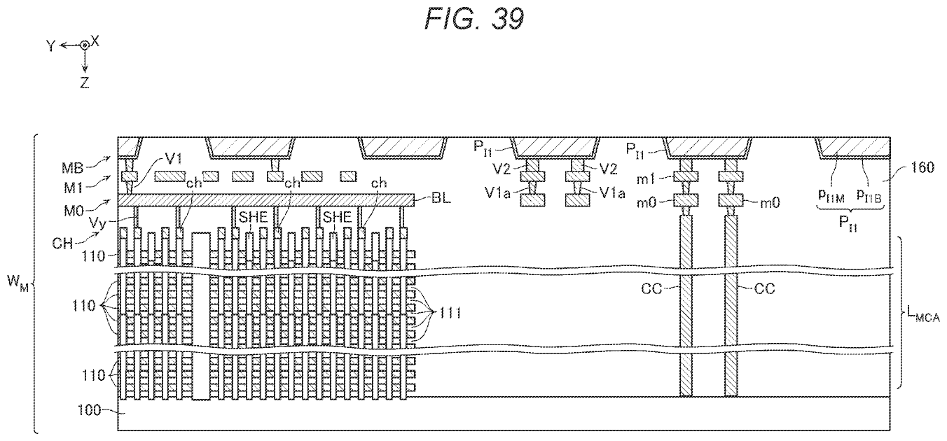

Next, for example, as shown in FIG. 39, the configuration in the wiring layer MB is formed. Accordingly, the wafer W_{M} corresponding to the chip C_{M} (FIG. 3) is formed.

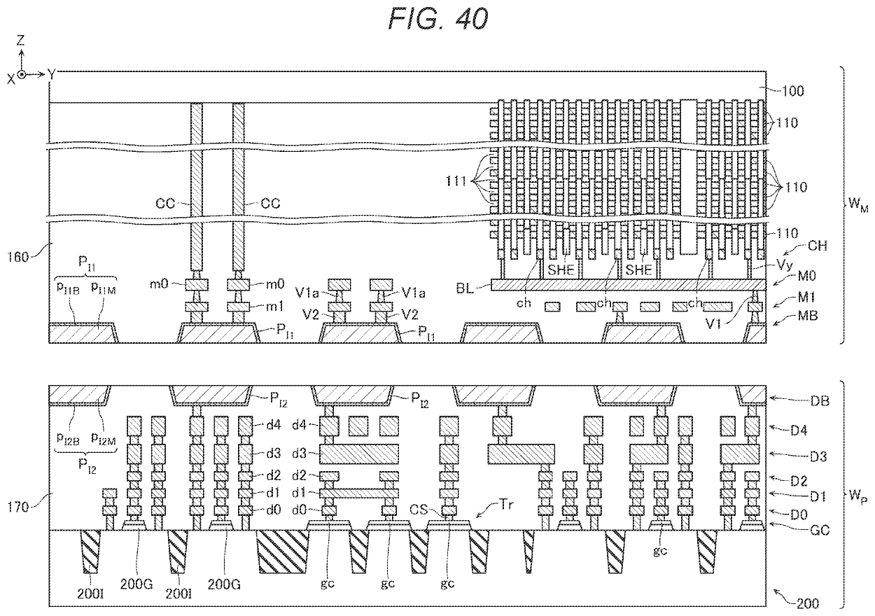

Next, for example, as shown in FIG. 40, the surface of the wafer W_{M} and the surface of the wafer W_{P} corresponding to the chip C_{P} (FIG. 3) face each other. The wafers W_{M} and W_{P} are bonded. Next, the back surface wiring layer MA and the like are formed to form the base structure L_{SB} described with reference to FIG. 3. In addition, singulation is performed by dicing.

### Comparative Example

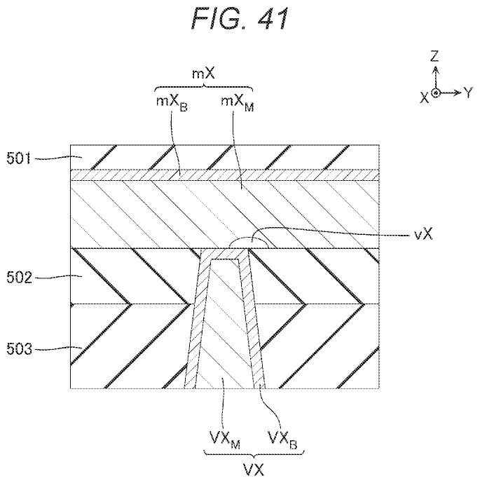

FIG. 41 is a schematic cross-sectional view showing a partial configuration of a semiconductor device according to a comparative example.

The semiconductor device according to the comparative example includes an insulating layer 501, an insulating layer 502 provided below the insulating layer 501, and an insulating layer 503 provided below the insulating layer 502. The insulating layers 501 and 503 contain, for example, silicon oxide (SiO₂). The insulating layer 502 contains, for example, silicon nitride (SiN).

In addition, the semiconductor device according to the comparative example includes a wiring mX embedded in a groove provided on a lower surface of the insulating layer 501. The wiring mX includes a conductive member mX_{M} and a barrier conductive film mX_{B} that covers the upper surface of the conductive member mX_{M}. The conductive member mX_{M} includes, for example, copper (Cu).

In addition, the semiconductor device according to the comparative example includes a via contact electrode VX. The via contact electrode VX includes a conductive member VX_{M} that extends in the Z direction through the insulating layers 503 and 502 and a barrier conductive film VX_{B} that covers the upper surface and the outer peripheral surface of the conductive member VX_{M}. The conductive member VX_{M} includes, for example, tungsten (W).

An upper end of the via contact electrode VX is in contact with a lower surface of the conductive member mX_{M}.

In the manufacturing of the semiconductor device according to the comparative example, in the step executed in a high temperature state, the wiring mX and the via contact electrode VX may thermally expand, and stress may be concentrated on the contact surface therebetween. After the execution of such a step, when the wiring mX and the via contact electrode VX are heat-shrunk, there is a concern that a void vX may be formed on the contact surface between the wiring mX and the via contact electrode VX as shown in the drawing. In particular, when the conductive member mX_{M} contains copper (Cu), the void vX is likely to be formed. As a result, there is a concern that the contact resistance between the wiring mX and the via contact electrode VX may increase or poor contact may occur between the wiring mX and the via contact electrode VX.

### Effect of First Embodiment

As described with reference to FIG. 9, the via contact electrode V1 according to the first embodiment includes an electrode region R_{V11} that extends in the Z direction and an electrode region R_{V12} that extends in the Y direction. In addition, the upper surface of the electrode region R_{V12}, both side surfaces of the electrode region R_{V12} in the X direction, and both side surfaces of the electrode region R_{V12} in the Y direction are in contact with the bit line BL.

The contact area between the via contact electrode V1 and the bit line BL according to the first embodiment is larger than the contact area between the via contact electrode VX and the wiring mX according to the comparative example. Therefore, according to the first embodiment, it is possible to prevent the concentration of the stress generated on the contact surface between the via contact electrode V1 and the bit line BL, and thus it is possible to prevent the generation of the void vX as described above.

In addition, in the first embodiment, as described with reference to FIGS. 7 and 9, the upper surface of the electrode region R_{V12} of the via contact electrode V1 is in contact with the lower surface of the portion P_{BLU} of the barrier conductive film BL_{B} of the bit line BL and is entirely covered with the portion P_{BLU} . According to such a configuration, the variation in the length of the electrode region R_{V12} in the Z direction can be prevented, and thus, the variation in the contact resistance between the via contact electrode V1 and the bit line BL can be prevented.

In addition, in the first embodiment, as described with reference to FIG. 7, both side surfaces of the electrode region R_{V12} of the via contact electrode V1 in the X direction are in contact with the portion P_{BLX} of the barrier conductive film BL_{B} of the bit line BL and are entirely covered with the portion P_{BLX}. According to such a configuration, the variation in the length of the electrode region R_{V12} in the X direction can be prevented, and thus, the variation in the contact resistance between the via contact electrode V1 and the bit line BL can be prevented.

As described with reference to FIG. 12, the via contact electrode V1a according to the first embodiment includes the electrode region R_{V1a1} that extends in the Z direction and the electrode region R_{V1a2} that has a substantially disk shape and extends in the X direction and the Y direction. In addition, the upper surface and the outer peripheral surface of the electrode region R_{V1a2} are in contact with the wiring m0a.

The contact area between the via contact electrode V1a and the wiring m0a according to the first embodiment is also larger than the contact area between the via contact electrode VX and the wiring mX according to the comparative example. Therefore, according to the first embodiment, it is possible to prevent the concentration of the stress generated on the contact surface between the via contact electrode V1a and the wiring m0a, and thus it is possible to prevent the generation of the void vX as described above.

In the first embodiment, as described with reference to FIGS. 10 and 12, the upper surface of the electrode region R_{V1a2} of the via contact electrode V1a is in contact with the lower surface of the portion P_{m0aU} of the barrier conductive film m0a_{B} of the wiring m0a and is entirely covered with the portion P_{m0aU}. According to such a configuration, the variation in the length of the electrode region R_{V1a2} in the Z direction can be prevented, and thus, the variation in the contact resistance between the via contact electrode V1a and the wiring m0a can be prevented.

In the first embodiment, as described with reference to FIGS. 10 and 12, the outer peripheral surface of the electrode region R_{V1a2} of the via contact electrode V1a is in contact with the conductive member m0a_{M} of the wiring m0a over the entire circumference. According to such a configuration, it is possible to prevent the contact resistance between the via contact electrode V1a and the wiring m0a.

### Second Embodiment

In the first embodiment, as described with reference to FIG. 9, the plurality of wiring regions R_{BL} provided in the conductive member BL_{M} of the bit line BL are separated from each other in the Y direction. In addition, as described with reference to FIGS. 10 and 12, the plurality of wiring regions Rₘ₀ₐprovided in the conductive member m0a_{M} of the wiring m0a are connected to each other via the wiring region R_{m0b}, and the conductive member m0a_{M} is continuous in the Y direction.

Such configurations are merely examples, and the specific configuration can be adjusted as appropriate. For example, the plurality of wiring regions R_{BL} provided in the conductive member BL_{M} of the bit line BL may be connected to each other, and the conductive member BL_{M} may be continuous in the Y direction, or the plurality of wiring regions Rₘ₀ₐ provided in the wiring m0a may be separated from each other in the Y direction.

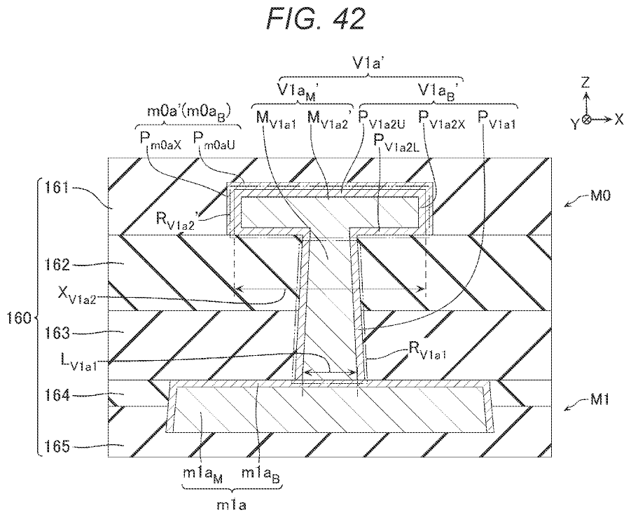

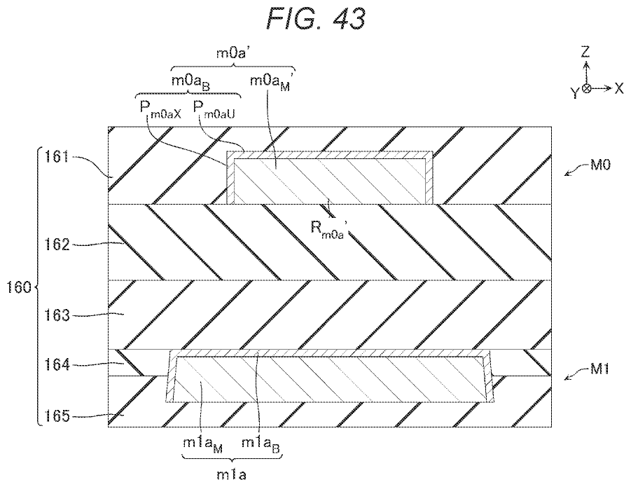

FIGS. 42 to 44 are schematic cross-sectional views showing a partial configuration of a semiconductor device according to a second embodiment.

The semiconductor device according to the second embodiment is basically configured in the similar manner to the semiconductor device according to the first embodiment. The semiconductor device according to the second embodiment includes a wiring m0a′ and a via contact electrode V1a′ instead of the wiring m0a and the via contact electrode V1a. Hereinafter, in the second embodiment, an example in which the wiring m0a′ other than the barrier conductive film m0a_{B} is separated in the Y direction via the via contact electrode V1a′ will be described.

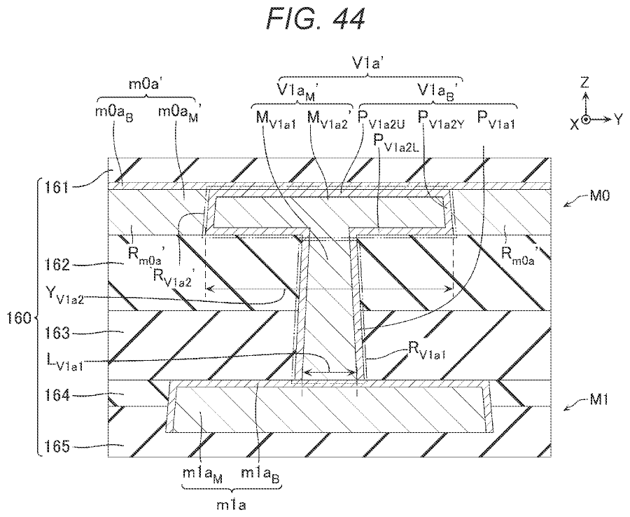

The wiring m0a′ is basically configured in the same manner as the wiring m0a, except that the wiring m0a′ includes the conductive member m0a_{M}′ instead of the conductive member m0a_{M}. The conductive member m0a_{M}′ is basically configured in the same manner as the conductive member m0a_{M}. As shown in FIG. 44, the conductive member m0a_{M}′ includes a plurality of wiring regions Rₘ₀ₐ′ arranged in the Y direction via the via contact electrode V1a′. The plurality of wiring regions Rₘ₀ₐ′ are separated from each other in the Y direction.

The via contact electrode V1a′ is basically configured in the same manner as the via contact electrode V1a, except that the electrode region R_{V1a2}′ is provided instead of the electrode region R_{V1a2}.

The electrode region R_{V1a2}′ is provided above the electrode region R_{V1a1} in the same manner as the electrode region R_{V1a2} and extends in the Y direction at a height position corresponding to the conductive member m0a_{M}′. Here, the length Y_{V1a2} (FIG. 44) of the electrode region R_{V1a2}′ in the Y direction is larger than the length X_{V1a2} (FIG. 42) of the electrode region R_{V1a2}′ in the X direction. In addition, the length X_{V1a2}of the electrode region R_{V1a2}′ in the X direction is larger than the length L_{V1a1} of the electrode region R_{V1a1} in the X direction and the Y direction (for example, the length L_{V1a1} of the electrode region R_{V11} in the X direction and the Y direction at the lower end).

As shown in FIG. 42, both side surfaces of the electrode region R_{V1a2}′ in the X direction are in contact with the portion P_{m0aX} of the barrier conductive film m0a_{B} and are entirely covered with the portion P_{m0aX}. In addition, as shown in FIG. 44, the electrode region R_{V1a2}′ is in contact with the side surface of the wiring region Rₘ₀ₐ′ in the Y direction.

The via contact electrode V1a′ includes a conductive member V1a_{M}′ and a barrier conductive film V1a_{B}′ instead of the conductive member V1a_{M} and the barrier conductive film V1a_{B}.

The conductive member V1a_{M}′ is basically configured in the same manner as the conductive member V1a_{M}, except that the conductive member V1a_{M}′ includes the conductive region M_{V1a2}′ instead of the conductive region M_{V1a2}. The conductive region M_{V1a2}′ extends in the X direction and the Y direction in the electrode region R_{V1a2}′.

The barrier conductive film V1a_{B}′ is basically configured in the same manner as the barrier conductive film V1a_{B}. Here, the barrier conductive film V1a_{B}′ includes a pair of portions P_{V1a2X} (FIG. 42) that cover both side surfaces of the conductive region M_{V1a2}′ in the X direction and a pair of portions P_{V1a2Y} (FIG. 44) that cover both side surfaces of the conductive region M_{V1a2}′ in the Y direction, instead of the portion P_{V1a2S} (FIGS. 10 and 12) of the barrier conductive film V1a_{B}. The portion P_{V1a2Y} is basically configured in the same manner as the portion P_{V1a2S} (FIG. 12) that covers both side surfaces of the conductive region M_{V1a2} in the Y direction. Both side surfaces of the portion P_{V1a2X} in the X direction are in contact with the portion P_{m0aX} of the barrier conductive film m0a_{B}, and are entirely covered with the portion P_{m0aX}.

The semiconductor device according to the second embodiment can be basically manufactured in the same manner as the semiconductor device according to the first embodiment. In the second embodiment, in the step described with reference to FIGS. 23 to 26, the portion P_{m0aX} of the barrier conductive film m0a_{B} is exposed.

Also in the semiconductor device according to the second embodiment, it is possible to prevent the generation of the voids vX as described with reference to FIG. 41 in the same manner as in the semiconductor device according to the first embodiment.

In addition, in the semiconductor device according to the second embodiment, as in the semiconductor device according to the first embodiment, the variation in the length of the electrode region R_{V1a2}′ in the Z direction can be prevented, and thus the variation in the contact resistance between the via contact electrode V1a′ and the wiring m0a′ can be prevented.

In addition, in the second embodiment, as described with reference to FIG. 42, the portion P_{V1a2X} of the barrier conductive film V1a_{B}′ of the via contact electrode V1a′ is in contact with the portion P_{m0aX} of the barrier conductive film m0a_{B} of the wiring m0a′, and is entirely covered with the portion P_{m0aX}. According to such a configuration, the variation in the length of the electrode region R_{V1a2}′ in the X direction can be prevented, and thus, the variation in the contact resistance between the via contact electrode V1a′ and the wiring m0a′ can be prevented.

### Third Embodiment

In the first embodiment, as shown in FIGS. 7 and 9, the via contact electrode V1 and the wiring CBL are formed separately. Therefore, the conductive member V1_{M} and the conductive member CBL_{M} are separated from each other in the Z direction. However, the via contact electrode V1 and the wiring CBL may be collectively formed. Therefore, the conductive member V1_{M} and the conductive member CBL_{M} may be continuous.

Similarly, in the first embodiment, as shown in FIGS. 10 and 12, the via contact electrode V1a and the wiring m1a are separately formed. Therefore, the conductive member V1a_{M} and the conductive member m1a_{M} are separated from each other in the Z direction. However, the via contact electrode V1a and the wiring m1a may be collectively formed. Therefore, the conductive member V1a_{M} and the conductive member m1a_{M} may be continuous.

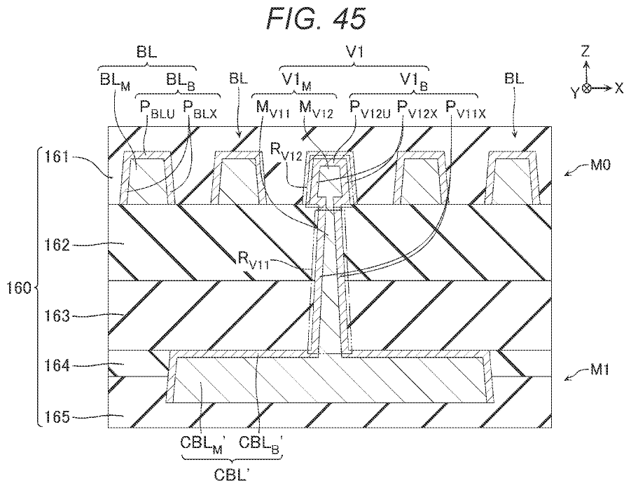

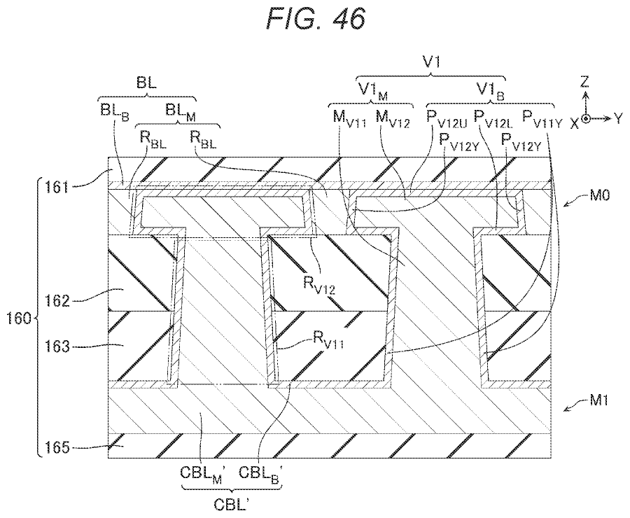

FIGS. 45 and 46 are schematic cross-sectional views showing a partial configuration of a semiconductor device according to a third embodiment. The semiconductor device according to the third embodiment is basically configured in the similar manner to the semiconductor device according to the first embodiment.

The semiconductor device according to the third embodiment includes a wiring CBL' instead of the wiring CBL. Hereinafter, an example in which the via contact electrode V1 and the wiring CBL′ are collectively formed in the third embodiment will be described.

The wiring CBL′ is basically configured in the same manner as the wiring CBL, except that the wiring CBL′ includes the conductive member CBL_{M}′ and the barrier conductive film CBL_{B}′ instead of the conductive member CBL_{M} and the barrier conductive film CBL_{B}. The conductive member CBL_{M}′ and the barrier conductive film CBL_{B}′ are each basically configured in the same manner as the conductive member CBL_{M} and the barrier conductive film CBL_{B}. Here, the conductive member CBL_{M}′ is continuous with the conductive member V1_{M} of the via contact electrode V1. In addition, the barrier conductive film CBL_{B}′ is formed integrally with the barrier conductive film V1_{B} of the via contact electrode V1.

The semiconductor device according to the third embodiment can be basically manufactured in the same manner as the semiconductor device according to the first embodiment.

However, in the third embodiment, in the step described with reference to FIGS. 27 and 28, a sacrificial layer is formed inside the contact hole V1A instead of the barrier conductive film V1B and the conductive member V1C.

After the execution of the steps described with reference to FIGS. 33 and 34, the sacrificial layer inside the contact hole V1A is removed.

In the step described with reference to FIGS. 35 and 36, the barrier conductive film CBLB and the barrier conductive film V1_{B} are collectively formed. In addition, the conductive member CBLC and the conductive member V1_{M} are collectively formed.

Also in the semiconductor device according to the third embodiment, the same effects as those of the semiconductor device according to the first embodiment can be realized.

### Other Embodiments

Hitherto, the semiconductor device according to the first to third embodiments is described. The above-described semiconductor device is merely an example, and specific configurations and the like can be appropriately adjusted.

For example, in the first to third embodiments, the via contact electrodes V1, V1a, and V1a′ include the barrier conductive films V1_{B}, V1a_{B}, and V1a_{B}′. However, the via contact electrodes V1, V1a, and V1a′ may not include the barrier conductive films V1_{B}, V1a_{B}, and V1a_{B}′.

Such a structure can be manufactured, for example, by omitting the formation of the barrier conductive film V1B in the step described with reference to FIGS. 27 and 28 or the step corresponding to the step.

In addition, for example, in the first to third embodiments, a NAND flash memory is exemplified as the semiconductor device. The semiconductor device may be a memory other than the NAND flash memory, or may not be a memory.

### Others

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a via contact electrode that extends in a first direction intersecting a surface of the substrate;
a first wiring that is connected to the via contact electrode and extends in a second direction intersecting the first direction; and
an insulating layer that is provided on a side of the first wiring opposite to the via contact electrode in the first direction,
wherein the first wiring includes
a first conductive member that extends in the second direction, and
a first barrier conductive film that covers a surface of the first conductive member, that is on a side of the insulating layer in the first direction,
the via contact electrode includes
a first electrode region that extends in the first direction, and
a second electrode region that is provided on the side of the insulating layer in the first direction with respect to the first electrode region and has a length in the second direction larger than a length of the first electrode region in the second direction, and
a surface of the second electrode region on the side of the insulating layer in the first direction is in contact with the first barrier conductive film and is entirely covered with the first barrier conductive film.

2. The semiconductor device according to claim 1,
wherein the first conductive member and the first electrode region are provided at positions that do not overlap each other when viewed in the first direction.

3. The semiconductor device according to claim 1,
wherein the first conductive member and the second electrode region are provided at positions that overlap each other when viewed in the second direction.

4. The semiconductor device according to claim 1,
wherein the first barrier conductive film includes
a first portion provided on one side in a third direction intersecting the first direction and the second direction with respect to the second electrode region, and
a second portion provided on the other side in the third direction with respect to the second electrode region,
the second electrode region and the first portion are separated from each other by a part of the first conductive member, and
the second electrode region and the second portion are separated from each other by another part of the first conductive member.

5. The semiconductor device according to claim 4,
wherein the first conductive member includes
a first wiring region provided on one side in the second direction with respect to the second electrode region, and
a second wiring region provided on the other side in the second direction with respect to the second electrode region, and
the first conductive member including the first wiring region and the second wiring region is continuous in the second direction through the part of the first conductive member and the other part of the first conductive member.

6. The semiconductor device according to claim 1,
wherein the first barrier conductive film includes
a first portion that is in contact with a surface of the second electrode region on one side in a third direction intersecting the first direction and the second direction, and
a second portion that is in contact with a surface of the second electrode region on the other side in the third direction.

7. The semiconductor device according to claim 6,
wherein the first conductive member includes
a first wiring region provided on one side in the second direction with respect to the second electrode region, and
a second wiring region provided on the other side in the second direction with respect to the second electrode region, and
the first wiring region and the second wiring region are separated from each other in the second direction.

8. The semiconductor device according to claim 1,
wherein the first conductive member includes
a first wiring region provided on one side in the second direction with respect to the second electrode region, and
a second wiring region provided on the other side in the second direction with respect to the second electrode region, and
the second electrode region is in contact with the first wiring region and the second wiring region.

9. The semiconductor device according to claim 1,
wherein the via contact electrode includes
a second conductive member including a first conductive region extending in the first direction in the first electrode region and a second conductive region extending in the second direction in the second electrode region, and
a second barrier conductive film covering a surface of the second conductive member on the side of the insulating layer in the first direction, the first barrier conductive film does not cover a surface of the first conductive member, that is on a side opposite to the insulating layer in the first direction, and the second barrier conductive film covers a surface of a portion of the second conductive region on the side opposite to the insulating layer in the first direction, the portion not overlapping the first conductive region when viewed in the first direction.

10. The semiconductor device according to claim 1, wherein the first conductive member contains copper (Cu), and the via contact electrode contains tungsten (W).

11. The semiconductor device according to claim 1, further comprising:
a plurality of conductive layers that are provided on the side of the insulating layer opposite to the via contact electrode in the first direction and arranged in the first direction;
a semiconductor pillar that extends in the first direction and faces the plurality of conductive layers; and
a charge storage film that is provided between the plurality of conductive layers and the semiconductor pillar,
wherein the first wiring is electrically connected to the semiconductor pillar.

12. The semiconductor device according to claim 11,
wherein the first wiring is a bit line of a NAND flash memory.

13. The semiconductor device according to claim 11, further comprising:
a second wiring that is connected to an end portion of the via contact electrode on a side opposite to the insulating layer in the first direction and is electrically connected to the first wiring via the via contact electrode,
wherein the second wiring extends in a third direction intersecting the first direction and the second direction.

14. The semiconductor device according to claim 1, further comprising:
a transistor provided on the surface of the substrate,
wherein the substrate is provided on a side of the first wiring opposite to the insulating layer in the first direction, and
the first wiring is electrically connected to the transistor via the via contact electrode.

15. A semiconductor device comprising:
a substrate;
a via contact electrode that extends in a first direction intersecting a surface of the substrate;
a wiring that is connected to the via contact electrode and extends in a second direction intersecting the first direction; and
an insulating layer that is provided on a side of the wiring opposite to the via contact electrode in the first direction,
wherein the wiring includes
a first conductive member that extends in the second direction, and
a first barrier conductive film that covers a surface of the first conductive member, that is on a side of the insulating layer in the first direction,
the via contact electrode includes
a first electrode region that extends in the first direction, and
a second electrode region that is provided on the side of the insulating layer in the first direction with respect to the first electrode region and has a length in the second direction larger than a length of the first electrode region in the second direction, and
the first barrier conductive film includes
a first portion that is in contact with a surface of the second electrode region on one side in a third direction intersecting the first direction and the second direction, and
a second portion that is in contact with a surface of the second electrode region on the other side in the third direction.

16. The semiconductor device according to claim 15,
wherein the first conductive member and the first electrode region are provided at positions that do not overlap each other when viewed in the first direction.

17. The semiconductor device according to claim 15,
wherein the first conductive member and the second electrode region are provided at positions that overlap each other when viewed in the second direction.

18. The semiconductor device according to claim 15,
wherein the first conductive member includes
a first wiring region provided on one side in the second direction with respect to the second electrode region, and
a second wiring region provided on the other side in the second direction with respect to the second electrode region, and
the first wiring region and the second wiring region are separated from each other in the second direction.

19. The semiconductor device according to claim 15,
wherein the first conductive member includes
a first wiring region provided on one side in the second direction with respect to the second electrode region, and
a second wiring region provided on the other side in the second direction with respect to the second electrode region, and
the second electrode region is in contact with the first wiring region and the second wiring region.

20. The semiconductor device according to claim 15,
wherein the via contact electrode includes
a second conductive member including a first conductive region extending in the first direction in the first electrode region and a second conductive region extending in the second direction in the second electrode region, and
a second barrier conductive film covering a surface of the second conductive member on the side of the insulating layer in the first direction,
the first barrier conductive film does not cover a surface of the first conductive member, that is on a side opposite to the insulating layer in the first direction, and
the second barrier conductive film covers a surface of a portion of the second conductive region on the side opposite to the insulating layer in the first direction, the portion not overlapping the first conductive region when viewed in the first direction.
